(19) United States
(12) Patent Application Publication
(10) Pub. No.: US 2026/0238834 A1
(43) Pub. Date: Aug. 13, 2026

(54) LOW-COMPLEXITY PARALLEL COMPRESSION FOR NEURAL NETWORK TRAINING

(71) Applicant: QUALCOMM Incorporated, San Diego, CA (US)

(72) Inventor: Amir Said, San Diego, CA (US)

(21) Appl. No.: 19/052,633

(22) Filed: Feb. 13, 2025

(51) Int. Cl. H04N 19/91; G06V 10/774; G06V 10/82; H04N 19/96

(52) U.S. Cl. CPC H04N 19/91; G06V 10/774; G06V 10/82; H04N 19/96

(57) ABSTRACT

This disclosure relates to a low-complexity parallel compression method for neural network training. The techniques of this disclosure include vector-based entropy coding utilizing vector range-tree coding and parallel vector operations, leveraging modern parallel processing capabilities. The techniques of this disclosure convert signed integers to unsigned integers, decodes the unsigned integers using a range-tree structure, and reconstructs image blocks. The techniques of this disclosure may be used in high-throughput image processing applications, such as neural network training.

### TECHNICAL FIELD

This disclosure relates to data and image compression.

### BACKGROUND

Many Artificial Intelligence (AI) applications, including camera and graphics pipelines, image and video processing, and complex generative models, utilize large sets of images during training. The training process requires numerous iterations, leading to an extremely large number of image accesses, which significantly impacts the overall training complexity and costs. Images need to be available as floating-point arrays for processing by training software, but images are typically stored in lossy and lossless compression formats. This necessitates constant decompression from slower disk storage and the use of substantial processor memory to store some decompressed images during training, posing serious limitations, especially on mobile devices.

### SUMMARY

This disclosure presents an apparatus and method for image processing that utilizes a vector-based entropy decoding method to enhance the efficiency and speed of image decompression. At a high-level, the techniques of this disclosure include accessing a plurality of encoded image blocks from memory, decoding the data for each block using the vector-based entropy decoding method, and reconstructing the decoded data into image blocks. The vector-based entropy decoding method described in this disclosure leverages the capabilities of modern processors, specifically utilizing Single-Instruction-Multiple-Data (SIMD) and Single-Instruction-Multiple-Thread (SIMT) features for synchronous parallel processing. This parallel processing capability significantly accelerates the decoding process, enabling faster access to decompressed images. By minimizing memory access to extra coding information and avoiding the decomposition of values before compression, the techniques of this disclosure better ensure efficient and rapid image decompression.

The techniques of this disclosure provide a highly efficient solution for image decompression, making it particularly suitable for applications benefiting from high-throughput image processing, such as neural network training. The ability to perform parallel vector operations enhances the overall processing speed, reducing the time required to access and decompress images. This efficiency translates to lower computational costs and improved performance, especially in environments with large datasets and high processing demands. The techniques of this disclosure thus offer a significant advancement in the field of image processing, providing a robust and scalable solution for modern computational needs.

In one example, this disclosure describes an apparatus for image decompression, the apparatus comprising at least one memory, and processing circuitry in communication with the at least one memory, the processing circuitry configured to retrieve a plurality of encoded image blocks from the memory, each encoded image block comprising encoded vectors, entropy decode, using parallel vector operations, the encoded vectors using vector-range tree coding (V-RTC) to generate decoded data, and reconstruct the decoded data into image blocks.

In another example, this disclosure describes a method for image decompression, the method comprising retrieving a plurality of encoded image blocks from memory, each encoded image block comprising encoded vectors, entropy decoding, using parallel vector operations, the encoded vectors using vector-range tree coding (V-RTC) to generate decoded data, and reconstructing the decoded data into image blocks.

In another example, this disclosure describes an apparatus for image compression, the apparatus comprising at least one memory, and processing circuitry in communication with the at least one memory, the processing circuitry configured to generate a plurality of image blocks from images stored in the memory, each image block comprising vectors, entropy encode, using parallel vector operations, the vectors using vector-range tree coding (V-RTC) to generate encoded data, and store the encoded data in the memory.

In another example, this disclosure describes a method for image compression, the method comprising generating a plurality of image blocks from images stored in memory, each image block comprising vectors, entropy encoding, using parallel vector operations, the vectors using vector-range tree coding (V-RTC) to generate encoded data, and storing the encoded data in the memory.

The details of one or more examples of the disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 is a block diagram illustrating an example computing device that may perform techniques of this disclosure.

FIG. 2 is a block diagram illustrating an example of 3D scene view generation using machine learning.

FIG. 3 is a block diagram illustrating an example of training multimodal large language models using image sets.

FIG. 4 is a conceptual diagram illustrating an example of a range tree.

FIG. 5 illustrates examples of how pairs of non-negative integers with a given maximum magnitude can be represented with symbols in a range 0, 1, . . . , 2 max(i, j).

FIG. 6 illustrates an example array of values from a transformation function.

FIG. 7 illustrates examples of how pairs of signed integers with a given maximum magnitude can be represented with symbols in range 0, 1, . . . , 8 max(|i|,|j|)−1.

FIG. 8 illustrates an alternative order for representing pairs of signed integers.

FIG. 9 illustrates an example scan order for 8×8 transform coefficients.

FIG. 10 illustrates an example of mapping pixel values in 2-dimensional arrays into vectors.

FIG. 11 illustrates example rate-distortion test results.

FIG. 12 illustrates example test results for lossy image compression compared to JPEG.

FIG. 13 illustrates example test results for lossy image compression compared to PNG.

FIG. 14 is a block diagram illustrating an example compression process of the disclosure.

FIG. 15 is a block diagram illustrating an example decompression process of the disclosure.

### DETAILED DESCRIPTION

Many AI applications, including camera and graphics pipelines, image and video processing, and complex generative models, utilize large sets of images during training. The training process typically requires numerous iterations, leading to a very large number (e.g., billions) of image accesses, which significantly impacts the overall training complexity and costs. Images need to be available as floating-point arrays for processing by training software, but they are typically stored in lossy and lossless compression formats. This necessitates constant decompression from slower disk storage and the use of substantial processor memory to store some decompressed images during training, posing serious limitations, especially on mobile devices.

The most commonly used image compression formats for neural network training are PNG and JPEG. The PNG format, designed for lossless image compression, often achieves compression ratios around 1.5:1, which is less efficient for images compared to other lossless formats. While PNG can store images uncompressed or compressed with a type of Lempel-Ziv universal entropy coding, the PNG format does not meet the high throughput requirements of modern AI training processes. The JPEG format, although widely supported and simple, was created over three decades ago and does not support parallel execution. This limitation prevents JPEG from fully exploiting the vector and multi-processing power available in modern computing systems used for neural network training. Other image compression standards, such as JPEG-2000 and JPEG-XR, offer somewhat better compression and additional image features but are not widely available in cameras and mobile devices. These newer formats often require more complex implementations, such as arithmetic coding for entropy coding, which can slow down decompression during training.

Consequently, the existing image compression methods are not optimized for the parallel processing capabilities of modern processors, leading to inefficiencies in the training process of neural networks. This disclosure describes an entropy coding method of low complexity for fast parallel compression and decompression of image blocks. The techniques of this disclosure include accessing a plurality of encoded image blocks from memory, decoding the data for each block using the vector-based entropy decoding method, and reconstructing the decoded data into image blocks. The vector-based entropy decoding method described in this disclosure leverages the capabilities of modern processors, specifically utilizing Single-Instruction-Multiple-Data (SIMD) and Single-Instruction-Multiple-Thread (SIMT) features for synchronous parallel processing.

This parallel processing capability significantly accelerates the decoding process, enabling faster access to decompressed images. By minimizing memory access to extra coding information and avoiding the decomposition of values before compression, the techniques of this disclosure better ensure efficient and rapid image decompression. The techniques of this disclosure better ensure that compressed images can be efficiently moved from large data sets on disk to small processor buffers, with fast and efficient decompression only when needed. This significantly reduces training costs and improves the overall efficiency of neural network training.

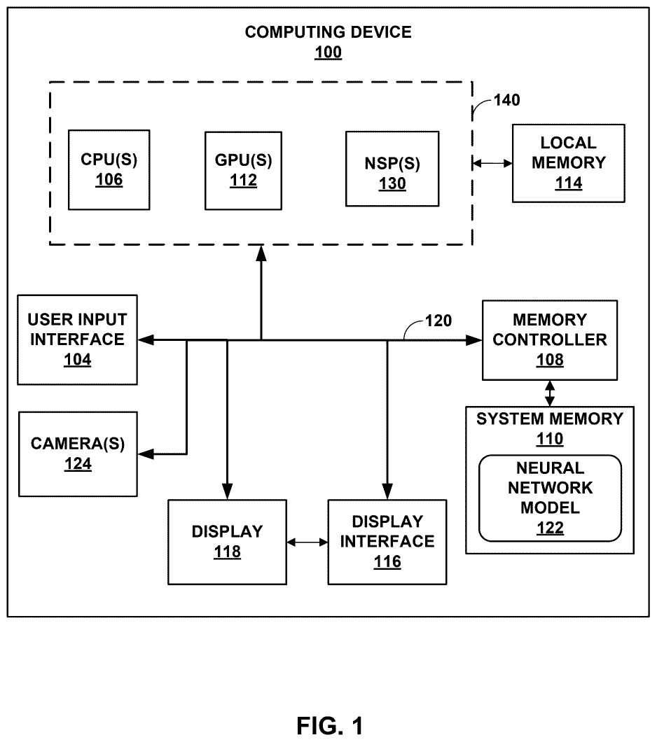

FIG. 1 is a block diagram illustrating an example computing device that may perform techniques of this disclosure. Computing device 100 may comprise a mobile device (such as, e.g., a smart phone, a mobile telephone, a cellular telephone, a satellite telephone, and/or a mobile telephone handset), a personal computer, a desktop computer, a laptop computer, a computer workstation, a video game platform or console, a landline telephone, an Internet telephone, a handheld device such as a portable video game device or a personal digital assistant (PDA), a personal music player, a video player, a display device, a television, a television set-top box, a server, an intermediate network device, a mainframe computer, a mobile computing device, a vehicle head unit, self-driving or autonomous driving vehicle, a robot, or any other type of device having imaging or video capabilities.

As illustrated in the example of FIG. 1, computing device 100 includes a user input interface 104, a CPU(S) 106, a memory controller 108, a system memory 110, a graphics processing unit (GPU) 112, a neural signal processor (NSP) 130, a local memory 114, a display interface 116, a display 118, bus 120, and one or more cameras 124. User input interface 104, CPU(S) 106, memory controller 108, GPU(S) 112, NSP(S) 130, display interface 116, and one or more cameras 124 may communicate with each other using bus 120. Bus 120 may be any of a variety of bus structures, such as a third-generation bus (e.g., a HyperTransport bus or an InfiniBand bus), a second-generation bus (e.g., an Advanced Graphics Port bus, a Peripheral Component Interconnect (PCI) Express bus, or an Advanced eXentisible Interface (AXI) bus) or another type of bus or device interconnect. It should be noted that the specific configuration of buses and communication interfaces between the different components shown in FIG. 1 is merely exemplary, and other configurations of computing devices and/or other graphics processing systems with the same or different components may be used to implement the techniques of this disclosure.

One or more cameras 124 may include any image capture hardware that includes one or more image sensors and one or more lens, and that is configured to capture at least one frame of image data and to transfer the at least one frame of image data to CPU(S) 106, GPU(S) 112, and/or NSP(S) 130.

CPU(s) 106 may comprise one or more general-purpose and/or special-purpose processors that controls operation of computing device 100. A user may provide input to computing device 100 to cause CPU(s) 106 to execute one or more software applications. The software applications that execute on CPU(s) 106 may include, for example, an operating system, a word processor application, an email application, a spread sheet application, a media player application, a video game application, a graphical user interface application, and/or other programs. The user may provide input to computing device 100 via one or more input devices (not shown) such as a keyboard, a mouse, a microphone, a touch pad or another input device that is coupled to computing device 100 via user input interface 104.

Memory controller 108 facilitates the transfer of data going into and out of system memory 110. For example, memory controller 108 may receive memory read and write commands, and service such commands with respect to system memory 110 in order to provide memory services for the components in computing device 100. Memory controller 108 is communicatively coupled to system memory 110. Although memory controller 108 is illustrated in the example computing device 100 of FIG. 1 as being a processing module that is separate from both CPU(s) 106 and system memory 110, in other examples, some or all of the functionality of memory controller 108 may be implemented on one or both of CPU(s) 106 and system memory 110.

System memory 110 may store program modules and/or instructions that are accessible for execution by CPU(s) 106 and/or data for use by the programs executing on CPU(s) 106. For example, system memory 110 may store user applications and graphics data associated with the applications. System memory 110 may additionally store information for use by and/or generated by other components of computing device 100. For example, system memory 110 may act as a device memory for one or more GPU(s) 112 and may store data to be operated on by GPU(s) 112 as well as data resulting from operations performed by GPU(s) 112. System memory 110 may include one or more volatile or non-volatile memories or storage devices, such as, for example, random access memory (RAM), static RAM (SRAM), dynamic RAM (DRAM), read-only memory (ROM), erasable programmable ROM (EPROM), electrically erasable programmable ROM (EEPROM), flash memory, a magnetic data media or an optical storage media.

In some aspects, system memory 110 may include instructions that cause CPU(s) 106, GPU(s) 112, and/or NSP(s) 130 to perform the functions ascribed in this disclosure to CPU(s) 106, GPU(s) 112, and NSP(s) 130. Accordingly, system memory 110 may be a computer-readable storage medium having instructions stored thereon that, when executed, cause one or more processors (e.g., CPU(s) 106, GPU(s) 112, and NSP(s) 130) to perform various functions.

In some examples, system memory 110 is a non-transitory storage medium. The term “non-transitory” indicates that the storage medium is not embodied in a carrier wave or a propagated signal. However, the term “non-transitory” should not be interpreted to mean that system memory 110 is non-movable or that its contents are static. As one example, system memory 110 may be removed from computing device 100, and moved to another device. As another example, memory, substantially similar to system memory 110, may be inserted into computing device 100. In certain examples, a non-transitory storage medium may store data that can, over time, change (e.g., in RAM).

GPU(s) 112 may be configured to perform graphics operations to render one or more graphics primitives to display 118. Thus, when one of the software applications executing on CPU(s) 106 requires graphics processing, CPU(s) 106 may provide graphics commands and graphics data to GPU(s) 112 for rendering to display 118. The graphics commands may include, e.g., drawing commands such as a draw call, GPU state programming commands, memory transfer commands, general-purpose computing commands, kernel execution commands, etc. In some examples, CPU(s) 106 may provide the commands and graphics data to GPU(s) 112 by writing the commands and graphics data to system memory 110, which may be accessed by GPU(s) 112. In some examples, GPU(s) 112 may be further configured to perform general-purpose computing for applications executing on CPU(s) 106.

GPU(s) 112 may, in some instances, be built with a highly parallel structure that provides more efficient processing of vector operations than CPU(s) 106. For example, GPU(s) 112 may include a plurality of processing elements that are configured to operate on multiple vertices or pixels in a parallel manner. The highly parallel nature of GPU(s) 112 may, in some instances, allow GPU(s) 112 to draw graphics images (e.g., GUIs and two-dimensional (2D) and/or three-dimensional (3D) graphics scenes) onto display 118 more quickly than drawing the scenes directly to display 118 using CPU(s) 106. In addition, the highly parallel nature of GPU(s) 112 may allow GPU(s) 112 to process certain types of vector and matrix operations for general-purpose computing applications more quickly than CPU(s) 106. In some examples, computing device 100 may make use of the highly parallel structure of GPU(s) 112 to perform parallel entropy coding.

GPU(s) 112 in the computing device 100 are designed to handle highly parallel tasks, making them also well-suited for general compute applications, including the execution of neural networks and other AI applications. GPU(s) 112 may be equipped with a large number of cores that can perform many operations simultaneously, which is ideal for the matrix and vector computations commonly found in AI workloads. This parallel processing capability allows GPU(s) 112 to efficiently execute complex algorithms required for training and inference in neural networks, significantly accelerating these processes compared to traditional CPUs.

GPU(s) 112 may execute Single-Instruction-Multiple-Data (SIMD) and Single-Instruction-Multiple-Thread (SIMT) operations to maximize their parallel processing capabilities. SIMD operations involve executing a single instruction on multiple data points simultaneously. This is particularly useful in scenarios where the same operation needs to be applied to a large dataset, such as applying a filter to an image or performing element-wise operations on arrays.

SIMT operations, on the other hand, extend the concept of SIMD by allowing multiple threads to execute the same instruction concurrently, but each thread can operate on different data. This is a key feature of modern GPUs, enabling them to handle thousands of threads at once. SIMT is particularly beneficial for executing neural network models, where each thread can process different parts of the input data or different neurons in a layer, thus speeding up the computation significantly.

Overall, the use of SIMD and SIMT operations in GPU(s) 112 allows for efficient parallel processing, making them a useful component for high-performance computing tasks, including AI and neural network applications.

GPU(s) 112 may, in some instances, be integrated into a motherboard of computing device 100. In other instances, GPU(s) 112 may be present on a graphics card that is installed in a port in the motherboard of computing device 100 or may be otherwise incorporated within a peripheral device configured to interoperate with computing device 100. In further instances, GPU(s) 112 may be located on the same microchip as CPU(s) 106 forming a system on a chip (SoC). GPU(s) 112 and CPU(s) 106 may include one or more processors, such as one or more microprocessors, application specific integrated circuits (ASICs), field programmable gate arrays (FPGAs), digital signal processors (DSPs), or other equivalent integrated or discrete logic circuitry.

NSP(s) 130, also known as Neural Processing Units (NPUs), are specialized hardware designed to accelerate the execution of neural networks and other AI applications. NSP(s) 130 in computing device 100 may be optimized for handling the specific computational patterns found in AI workloads, such as matrix multiplications and tensor operations, which are prevalent in neural network training and inference. NSP(s) 130 may be equipped with a large number of processing elements that can perform operations in parallel, making them highly efficient for executing neural networks. This parallelism allows NSP(s) 130 to handle the vast amounts of data and complex computations used by AI models, significantly speeding up tasks such as image recognition, natural language processing, and other machine learning applications. Like GPU(s) 112, NSP(s) 130 may execute SIMD and/or SIMT instructions and operations.

CPU(s) 106, GPU(s) 112, and NSP(s) 130 may together be referred to as one or more processors 140. In describing the various techniques that may be performed by one or more processors 140, it should be understood that such techniques may be performed by one or more of CPU(s) 106, GPU(s) 112, and NSP(s) 130. It should be understood that the techniques disclosed herein are not necessarily limited to being performed by CPU(s) 106, GPU(s) 112, and/or NSP(s) 130, but may also be performed by any other suitable hardware, device, logic, circuitry, processing units, and the like of computing device 100.

GPU(s) 112 and NSP(s) 130 may be directly coupled to local memory 114. Thus, GPU(s) 112 and NSP(s) 130 may read data from and write data to local memory 114 without necessarily using bus 120. In other words, GPU(s) 112 and NSP(s) 130 may process data locally using a local storage, instead of off-chip memory. This allows GPU(s) 112 and NSP(s) 130 to operate in a more efficient manner by eliminating the need of GPU(s) 112 and NSP(s) 130 to read and write data via bus 120, which may experience heavy bus traffic. In some instances, however, GPU(s) 112 and NSP(s) 130 may not include a separate cache, but instead utilize system memory 110 via bus 120. Local memory 114 may include one or more volatile or non-volatile memories or storage devices, such as, e.g., random access memory (RAM), static RAM (SRAM), dynamic RAM (DRAM), erasable programmable ROM (EPROM), electrically erasable programmable ROM (EEPROM), flash memory, a magnetic data media or an optical storage media.

CPU(s) 106 may offload processing to GPU(s) 112 and NSP(s) 130, such as tasks that require massive parallel operations. As one example, graphics processing requires massive parallel operations, and CPU(s) 106 may offload such graphics processing tasks to GPU(s) 112. However, other operations such as matrix operations may also benefit from the parallel processing capabilities of GPU(s) 112 and NSP(s) 130. In these examples, CPU(s) 106 may leverage the parallel processing capabilities of GPU(s) 112 and NSP(s) 130to cause GPU(s) 112 and NSP(s) 130to perform non-graphics related operations, such as processing tasks related to AI and/or neural networks.

CPU(s) 106, GPU(s) 112, and/or NSP(s) 130 may store image data in a frame buffer that is allocated within system memory 110. Display interface 116 may retrieve the data from the frame buffer and configure display 118 to display the image represented by the rendered image data. In some examples, display interface 116 may include a digital-to-analog converter (DAC) that is configured to convert the digital values retrieved from the frame buffer into an analog signal consumable by display 118. In other examples, display interface 116 may pass the digital values directly to display 118 for processing.

Display 118 may include a monitor, a television, a projection device, a liquid crystal display (LCD), a plasma display panel, a light emitting diode (LED) array, a cathode ray tube (CRT) display, electronic paper, a surface-conduction electron-emitted display (SED), a laser television display, a nanocrystal display, an organic light-emitting-diode (OLED) display, or another type of display unit. Display 118 may be integrated within computing device 100. For instance, display 118 may be a screen of a mobile telephone handset or a tablet computer. Alternatively, display 118 may be a stand-alone device coupled to computing device 100 via a wired or wireless communications link. For instance, display 118 may be a computer monitor or flat panel display connected to a personal computer via a cable or wireless link.

System memory may store neural network model 122. Neural network model 122 may include one or more artificial neural networks (also referred to as neural networks) trained to receive input data of one or more types and to, in response, provide output data of one or more types.

A neural network (e.g., neural network model 122) may include a trainable or adaptive algorithm utilizing nodes that define rules. For example, a respective node of a plurality of nodes may utilize a function, such as a non-linear function or if-then rules, to generate an output based on an input. A neural network may include three types of layers of nodes, namely an input layer, one or more hidden layers, and an output layer. The input layer may receive inputs, such as values from which the neural network as a whole generates an output. The output of each node of the input layer may be provided to each node of a first layer of hidden layers. Each input from the input layer may be multiplied by a neural network weight and then summed at each node of hidden layers. Such weights are determined or adjusted during training of neural network to establish a relationship between the input data and output data. Output of each node of the first hidden layer are provided to each node of a next hidden layer, and so on, when there are more than one hidden layer. The output layer may be provided with the output of each node of the last hidden layer. The output layer may include a transfer function and may output an inference, prediction, classification, etc. which is based on the input data and the neural network weights.

A respective node of a plurality of nodes of a layer may be connected to one or more different nodes of the plurality of nodes along an edge, such that the output of the respective node includes the input of the different node. The functions may include neural network weights that may be determined or adjusted using a training set of inputs and desired outputs along with a learning rule, such as a back-propagation learning rule. The back-propagation learning rule may utilize one or more error measurements comparing the desired output to the output produced by the neural network to train the neural network by varying the parameters to minimize the one or more error measurements.

In some examples, neural network model 122 is trained to perform classification of input data. That is, neural network model 122 may be trained to label input data to classify input data into one or more classes or categories. Neural network model 122 may perform classification of input data by determining, for the input data, a confidence score for each of a plurality of classes that indicates a degree to which it is believed that the input data should be classified into the corresponding class. In other examples, neural network model 122 may determine a probabilistic distribution over a set of classes to indicate the probability that the input data belongs to each of the set of classes.

In some examples, neural network model 122 may be trained to perform computer vision tasks such as image classification, object detection, and/or image segmentation. Such computer vision tasks may be useful for computer vision applications such as autonomous driving. For example, neural network model 122 may be trained to perform image classification to determine which objects are in an image or video, such as by being trained to classify an image as either including a particular object or not including the particular object and by assigning one or more labels to the image. In another example, neural network model 122 may be trained to perform object detection to detect what objects are in an image or video and to specify where each of the objects are in the image, and neural network model 122 may be trained to assign one or more labels to each of the one or more objects in the image. In some examples, neural network model 122 may be trained to perform image segmentation to separate an image into regions that delineate potentially meaningful areas for further processing.

In some examples, neural network model 122 may perform one or more computer vision tasks on images captured by one or more cameras 124. That is, one or more cameras 124 may capture an image, and one or more processors 140 may input the image captured by one or more cameras 124 into neural network model 122 to perform one or more computer vision tasks, such as image classification, object detection, and/or image segmentation on the image.

In accordance with one or more aspects of this disclosure, computing device 100 may be configured to perform data compression and decompression techniques. In particular, as will be described in more detail below, computing device 100, using GPU(s) 112 and/or NSP(s) 130 may perform data compression and decompression techniques using parallel processing operations. While this disclosure will be described with reference to compression and decompression images, e.g., for use in training neural network model 122, the techniques of this disclosure may be used to compress and decompress any types of data.

In one example of the disclosure, as will be explained in more detail below, computing device 100 may be configured to retrieve a plurality of encoded image blocks from the memory, each encoded image block comprising encoded vectors. entropy decode, using parallel vector operations, the encoded vectors using vector-range tree coding (V-RTC) to generate decoded data, and reconstruct the decoded data into image blocks. In reciprocal manner, computing device 100 may also be configured to generate a plurality of image blocks from images stored in the memory, each image block comprising vectors, entropy encode, using parallel vector operations, the vectors using vector-range tree coding (V-RTC) to generate encoded data, and store the encoded data in the memory.

As discussed above, for AI applications related to images and videos, it is typical to constantly process images (e.g., compress and decompress) during training. In nearly all cases, training is done using a floating-point representation (even when using integer arithmetic) and the image pixel arrays are converted and available in the processor (CPU, GPU, NSP) memory for the training processing operations.

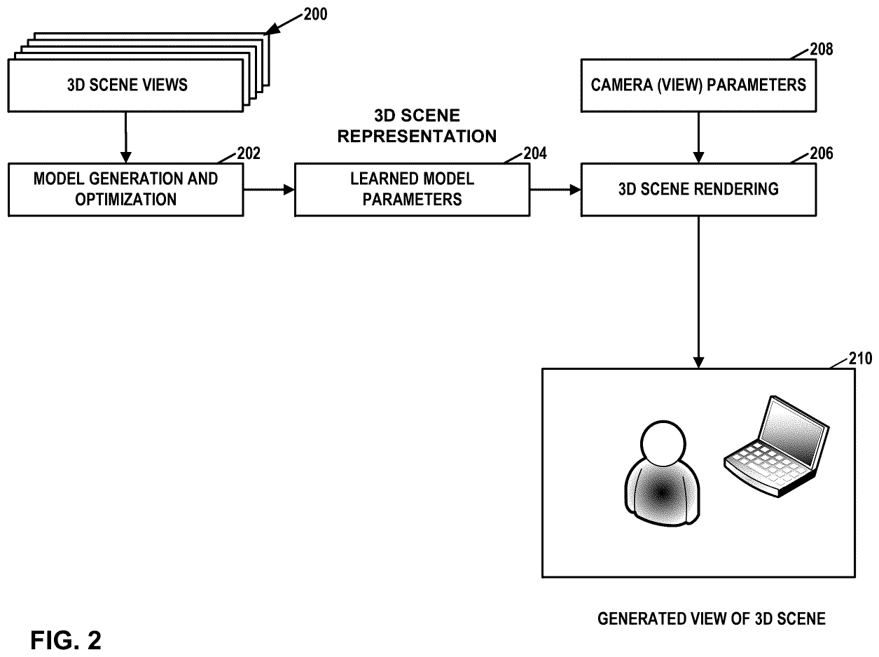

FIG. 2 is a block diagram illustrating an example of 3D scene view generation using machine learning. The process of generating and optimizing 3D models using machine learning techniques begins with the 3D scene views 200. 3D scene views 200 includes a collection of different perspectives or angles of a particular scene, which are utilized during the training phase of neural networks. These views are used for applications such as novel view synthesis, where the goal is to create new viewpoints of a scene that were not originally captured. Typically, these views are stored in a compressed format to optimize storage and processing efficiency. During training, the compressed views are decompressed and converted into floating-point arrays, which are then fed into the neural network for processing. Efficient handling and processing of these views may be important to reduce training time and computational costs, especially when dealing with large datasets.

Following this, the model generation and optimization 202 is responsible for creating and refining the neural network models that process 3D scene views 200. This includes using machine learning algorithms to train models that can accurately interpret and generate new views of a scene. The optimization process includes adjusting the model parameters to minimize error and improve performance, typically achieved through techniques such as stochastic gradient descent. Model generation and optimization 202 relies on the data provided by 3D scene views 200 to learn and improve. Efficient compression and decompression of the scene views better ensures that the model can be trained effectively without being bottlenecked by data access speeds.

Learned model parameters 204 represents the set of parameters that have been adjusted and optimized during the training process of the neural network model. These parameters are significant as they define the behavior and accuracy of the model in generating new 3D scene views. Typically, the parameters are stored in a compressed format to save space and facilitate quick access during model execution. Learning these parameters involves iteratively adjusting them based on the input data from 3D scene views 200 and the feedback received during the optimization phase. The efficiency of this process is enhanced by model generation and optimization 202, which ensures that the parameters are fine-tuned to achieve optimal performance.

3D scene rendering 206 is responsible for converting the 3D scene representation into a visual output that can be displayed to users. This process involves translating the digital model into a format that can be rendered on a screen, taking into account factors such as lighting, shading, and perspective. The rendering process is computationally intensive and benefits greatly from the parallel processing capabilities of modern GPUs and neural processors. The efficiency of 3D scene rendering 206 component is important for applications that require real-time rendering, such as video games and simulations. The component interacts with learned model parameters 204 to ensure that the rendered output accurately reflects the trained model's understanding of the scene.

Camera (view) parameters 208 component to the set of parameters that define the position, orientation, and settings of a virtual camera used to capture new views of a 3D scene. These parameters are important for generating novel views that were not part of the original dataset. Camera (view) parameters 208 are typically adjusted based on the requirements of the application and the desired output.

Finally, the generated view of 3D Scene 210 is the final output of the process, representing a new perspective of the 3D scene that has been synthesized by the neural network. This view is created using the learned model parameters 204 and the camera (view) parameters 208, and is rendered by 3D scene rendering 206. The generated view of 3D scene 210 is the culmination of the training and optimization process, showcasing the neural network's ability to create realistic and accurate representations of scenes from novel viewpoints.

In the example of FIG. 2, a set of different scene views are used during training. In this case, even though the number of views is relatively small, it may be impossible to have all decompressed images stored in processing memory.

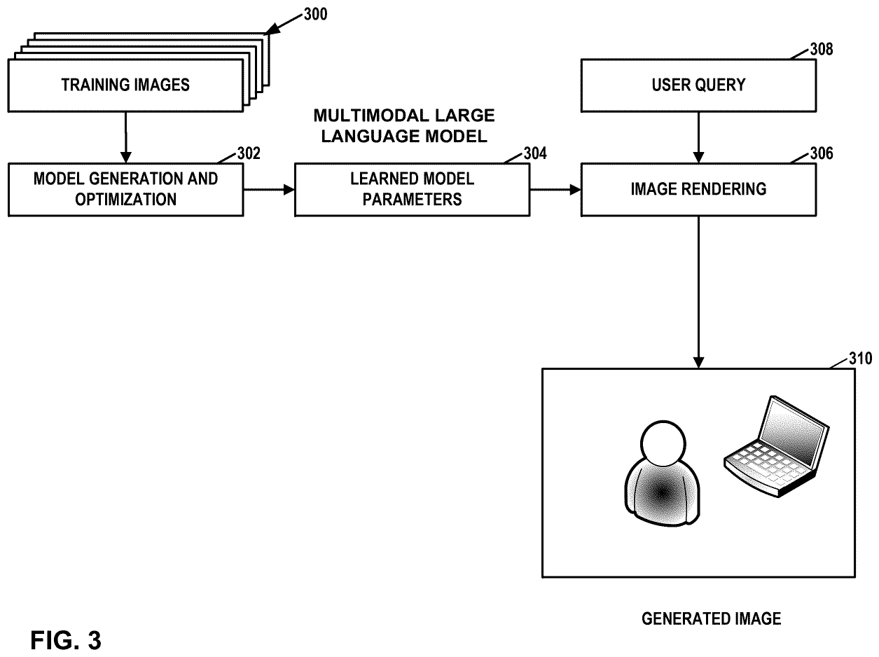

FIG. 3 is a block diagram illustrating an example of training multimodal large language models using image sets. Complex applications like multimodal large language models also employ images during training, but in those cases the training set is much larger, requiring constant access to image data on large disk arrays.

Training images 300 are used in the process of training multimodal large language models. These images serve as the foundational data set that the neural network utilizes to learn and adapt. The images are typically stored in compressed formats to optimize storage and processing efficiency. During training, these compressed images are decompressed and converted into floating-point arrays, which are then fed into the neural network for processing. The efficient handling and processing of these images are important for reducing training time and computational costs, especially when dealing with large datasets. Training images 300 are used by model generation and optimization 302, providing the necessary data for the neural network to learn and improve.

Model generation and optimization 302 is responsible for creating and refining the neural network models that process training images 300. This may involve using advanced machine learning algorithms to train models that can accurately interpret and generate new data from the input images. The optimization process includes adjusting the model parameters to minimize error and improve performance, typically achieved through techniques such as stochastic gradient descent. Model generation and optimization 302 uses the data provided by the training images 300to learn and improve. Efficient compression and decompression of training images 300 better ensures that the model can be trained effectively without being bottlenecked by data access speeds.

Learned model parameters 304 represent the set of parameters that have been adjusted and optimized during the training process of the neural network model. These parameters are significant as they define the behavior and accuracy of the model in generating new data. Typically, the parameters are stored in a compressed format to save space and facilitate quick access during model execution. Learning these parameters involves iteratively adjusting them based on the input data from training images 300 and the feedback received during the optimization phase.

User query 308 represents the input or request made by a user to the system. This query can take various forms, such as a text prompt, an image, or a combination of both, depending on the capabilities of the Multimodal Large Language Model. User query 308 is processed by the model to generate a response or output that aligns with the user's request.

Image rendering 306 is responsible for converting the output of the Multimodal Large Language Model into a visual format (e.g., generated image 31) that can be displayed to the user. This process involves translating the model's output into an image or visual representation that aligns with the user's query.

The most used training algorithm for neural networks is stochastic gradient, which includes accessing images in pseudo-random order for each iteration. To reduce network coefficient training it is also common to use, at each iteration, only smaller pseudo-random crops within each image. Trying to solve the problems associated with image access by converting images to much lower resolution results in biased training, which degrades the solution.

The consequence is that the process of loading images from a disk-based training set to processor memory greatly affects training speed. The “image loading” software component must efficiently balance the need to load and convert images from a slower disk memory to the processor's internal random-access memory, which is much faster but much smaller.

The software platforms available for training neural networks support the formats used by the most popular image and video data sets, which are implementations of the PNG and JPEG formats. The properties, advantages, and limitations of those image compression formats are presented next, followed by a discussion on why other formats are not commonly used.

The PNG format for lossless image compression can store the image uncompressed, or optionally compressed with a type of Lempel-Ziv universal entropy coding. While formats designed specifically for lossless image compression (e.g., JPEG-LS), can provide compression ratios around 2:1, the PNG universal compression is much less efficient for images, and typically only achieves image compression ratios around 1.5:1.

Even more important is the fact that while some applications need high quality images during training, lossless compression is not strictly required. In fact, near-lossless compression can also provide very high reproduction quality with compression ratios starting from around 4:1. For most applications, the quality obtained using 10:1 or larger compression ratios is sufficiently high.

The JPEG standard format was created more than three decades ago, and is universally supported by digital cameras, web browsers, etc. Thus, most image training sets start from JPEG-compressed versions. In some cases, all images are converted to PNG due to training software requirements. One main advantage of JPEG is that it is a very simple standard, using a compression method that has very low computational complexity, based on the Discrete Cosine Transform (DCT) and Huffman codes for entropy coding.

A disadvantage of the JPEG standard is that it does not define some compression options, like DCT precision, color transformation, and chroma subsampling. Other options, like Huffman codes and quantization tables (for visual quality optimization), do not have standard-defined default values and thus must be added to the compressed data. JPEG compression software allows control over all options, but those are not well-known, and users normally use only the implementation-dependent default options, which may not be optimal for their application.

There are other image compression standards that were proposed for replacing JPEG, like JPEG-2000 and JPEG-XR, but none is widely available in cameras and mobile devices. Those standards and other new formats provide somewhat better compression, and support additional image features, but those have not provided enough motivation to use in neural network training. At the same time, the new compression methods may require significantly more complex implementations, for example using arithmetic coding for entropy coding, which can make decompression during training even slower.

The JPEG format has been considered the best choice for neural network training because it supports efficient lossy and near-lossless compression with relatively low computational complexity. However, the JPEG format has the fundamental limitation that it was not designed for parallel execution, and thus it cannot exploit the vector and multi-core processing power available in the modern computing systems used for neural network training, such as GPU(s) 112 and/or NSP(s) 130 of FIG. 1.

A main performance bottleneck in current image compression formats is the entropy coding process. Even if the other compression stages, like color conversion and DCT computation, are fully parallelized, all data components need to be sequentially arranged in a single standard-compliant bitstream for entropy encoding and decoding, with algorithms that cannot be parallelized. Since other image compression formats use similar forms of non-parallelizable entropy coding, they have the same limitations.

For more efficient execution, new image compression methods need to be designed to match the features of current modern processor architectures, and exploit both synchronous (e.g., SIMD/SIMT) and asynchronous parallelization. For instance, image compression/decompression techniques should:
1. Minimize memory access to extra coding information, like codeword tables, element-dependent quantization, and arrays of coding contexts.
2. Avoid decomposing values before compression, like separate compression for value signs, individual bits or bins, etc.
3. Allow large number of data bits to be encoded together, in regular patterns (i.e., limit randomness to data and not to execution path).
4. Exploit data dependencies to allow better compression but avoid using complicated context generation.
   In the next sections, this disclosure describes an entropy coding method, called Vector-Range Tree Coding (V-RTC) that addresses those objectives.

The simplest form of parallelization for coding an image is to segment the image in blocks (e.g., stripes or tiles), and code the blocks independently. For this approach, it is beneficial to:
1. Use coding methods that avoid dependencies between the blocks that are coded independently.
2. Efficiently compress the data structures that store the information needed for parallel decoding (entropy decoder entry points).
   In the next sections, this disclosure describes an entropy coding method called V-RTC that may be used to entropy encode and decode data, including data related to compressing images. The V-RTC techniques of this disclosure extend a form of asynchronous parallelized compression to also enable synchronous parallelization, using SIMD/SIMT vector instructions.

### Vector-Range Tree Coding (V-RTC)

It has been shown that a universal coding method called Range Tree Coding (RTC), can efficiently exploit data dependencies in data arrays by using a tree structure where maximum magnitudes are progressively encoded. RTC is a method designed to efficiently compress sequences of data by exploiting the hierarchical structure of data magnitudes. RTC includes organizing data into a binary tree structure, where each node represents a range of values, and the maximum and minimum values within that range are progressively encoded. This hierarchical approach allows for efficient compression by reducing the number of bits required to represent data, particularly when the data values are closely grouped. The RTC method is particularly effective for compressing data with asymmetric distributions, where the values are not evenly spread across the range.

The RTC process begins by constructing arrays that store the maximum and minimum values of data subsets, organized in a binary tree format. This organization allows for a recursive partitioning of data, where each node in the tree represents a subset of the data, and the maximum and minimum values are used to constrain the range of possible values for each data element. By encoding the maximum and minimum values at each node, RTC can efficiently compress the data by using fewer bits for elements that fall within a known range. This approach is advantageous because it allows for the compression of data without the need for complex arithmetic coding, relying instead on simpler binary prefix codes.

One of the key features of RTC is its ability to handle data with varying magnitudes and distributions without requiring prior knowledge of the statistical properties of the data. This universality makes RTC suitable for a wide range of applications, as RTC can adapt to different data characteristics and still achieve efficient compression. RTC is particularly useful for applications where data values are tightly clustered, as RTC can significantly reduce the bit rate compared to traditional coding methods. Additionally, RTC's tree-based structure allows for parallel processing, making it well-suited for modern computing architectures that leverage parallelism to improve performance.

In practice, RTC can be implemented using simple algorithms that traverse the binary tree structure to encode and decode data. The encoding process involves determining the maximum and minimum values for each node and using these values to constrain the range of possible values for each data element. The decoding process follows a similar approach, using the encoded maximum and minimum values to reconstruct the original data. This simplicity, combined with its efficiency and adaptability, makes RTC a powerful tool for data compression, particularly in scenarios where data must be processed quickly and efficiently, such as in real-time video and image compression applications.

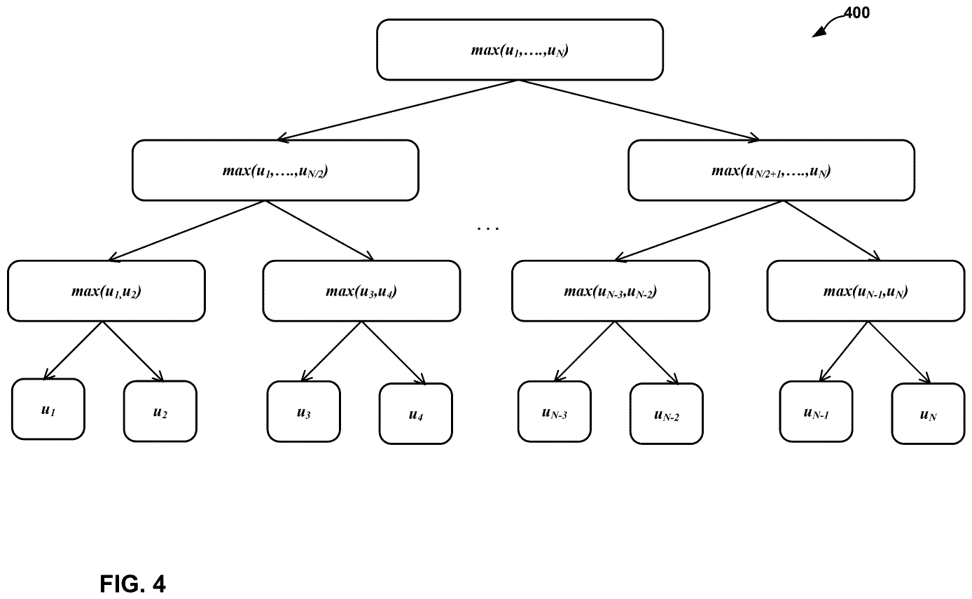

The techniques of this disclosure include modifying RTC to enable synchronous parallel compression on vectors, to exploit the SIMD/SIMT features of moder processors, creating a new version called Vector-Range Tree Coding (V-RTC). The tree data organization of V-RTC is the same as RTC, but integers in the tree nodes are replaced with D-dimensional vectors of integer values, as shown in FIG. 4.

FIG. 4 is a conceptual diagram illustrating an example of a range tree. In FIG. 4, the nodes of tree 400 represent the maximum values of subsets of data, denoted as max(u₁, u₂, . . . , u_{d}). In the context of RTC, the values u in tree 400 are unsigned integers, which can represent various data types such as transform coefficients, pixel values, luma sample values, chroma sample values, or any other type of data that may be entropy coded. That is, the techniques of this disclosure, while useful with image compression, may be used to compress and decompress many types of data. The unsigned integers are organized in a manner that allows for efficient compression by reducing the number of bits required to represent the data, particularly when the data values are closely grouped.

The RTC method is designed to work with arrays of unsigned integers, and the tree structure facilitates the encoding and decoding processes by using the maximum values at each node to constrain the range of possible values for each data element. This approach allows for the compression of data without the need for complex arithmetic coding, relying instead on simpler binary prefix codes.

In the context of V-RTC, the integers in the tree nodes of RTC are replaced with D-dimensional vectors of integer values. This modification enables synchronous parallel compression on vectors, leveraging the Single-Instruction-Multiple-Data (SIMD) and Single-Instruction-Multiple-Thread (SIMT) features of modern processors. By using vectors instead of scalar integers, V-RTC can exploit data dependencies more effectively, allowing for independent parallel execution without compression losses. This makes V-RTC particularly suitable for high-throughput image processing applications, such as neural network training, where efficient and rapid image decompression is important.

Throughout this disclosure, vectors are represented using bold fonts and vector operations are done per element, such as:

$$max ( x , y ) {=}^{def} [ max ( {x}_{1} , {y}_{1} ) , max ( {x}_{2} , {y}_{2} ) , ⋯ , max ( {x}_{D} , {y}_{D} ) ] . \qquad ( 1 )$$

Equation (1) defines a vectorized operation that computes the element-wise maximum between two vectors, x and y, each of dimension D. In this context, each element of the resulting vector is the maximum of the corresponding elements from the input vectors. This operation is particularly useful in scenarios where parallel processing is employed, as it allows for simultaneous computation of maximum values across multiple data points.

RTC has shown the advantage of having all the information needed for efficient compression contained in a single array, with the number of bits used for entropy coding obtained directly from the maximum magnitude values in the tree. Below we list some features of RTC, that make it a good choice for fast parallel compression implementations.
For better compression RTC can effectively implement a form of context-based data compression, but without requiring the much more complex process of context selection and updating used by context-based arithmetic coding.
Arithmetic coding and related contexts, and other forms of adaptive compression have internal states that impede parallelization, while RTC contexts are strictly contained to the tree data, allowing independent parallel execution without compression losses.
RTC uses only binary coding that is much simpler and faster than arithmetic coding, and can also be easily parallelized.
RTC only needs a fixed-size memory for tree data and does not need extra storage for tables of pre-defined codewords, or tables needed for faster binary decoding (e.g., for adaptive codes like Golomb-Rice, Elias, and exponential Golomb).

RTC is defined to work with arrays of unsigned integers. For image compression, a typical data type that may be compressed are transform coefficients, e.g., after a DCT has been applied to pixel data (e.g., for still images) or residual data (e.g., for encoded frames of video data). Transform coefficients are often quantized. However, transform coefficients may be positive or negative. That is, transform coefficients are signed integers, and not unsigned integers. Other image and video compression methods deal with this problem by decomposing data values. For example, MPEG video compression standards decompose the values to only code binary data symbols (bins), while JPEG decompose the values into three components: magnitude group, magnitude offset bits, and sign bit.

Data decomposition and separate coding can make the compression method more intuitive, but significantly slower because the encoder and decoder need more instructions for the decomposition and using different compression methods for each component. To avoid those problems and enable faster parallel coding, when processing data using the V-RTC techniques of this disclosure, computing device 100 may first convert signed to unsigned integers using the following transformations:

$$u [ n ] = \{ \begin{matrix}2 n , & n \geq 0 , \\ - 1 - 2 n , & n < 0 ,\end{matrix} \qquad ( 2 )$$

which has inverse transformation

$$n [ u ] = \{ \begin{matrix}u / 2 , & u is even , \\ - ( u + 1 ) / 2 , & u is odd .\end{matrix} \qquad ( 3 )$$

Equations (2) and (3) describe a transformation process used in Vector-Range Tree Coding (V-RTC) to convert signed integers into unsigned integers and vice versa. These transformation may enable more efficient parallel processing and compression of data.

Equation (2) defines the transformation from a signed integer n to an unsigned integer u[n]. This transformation maps each signed integer to a unique unsigned integer, allowing the data to be processed in a format that is more suitable for certain compression techniques. The transformation ensures that positive and negative values are handled consistently, although it does not preserve the symmetry between them.

Equation (3) provides the inverse transformation, converting an unsigned integer u back to a signed integer n[u]. This inverse transformation allows the original signed integer values to be recovered from the unsigned integers. The transformation is designed to be efficient, using only basic arithmetic and logic operations, which can be easily implemented in parallel processing environments.

Together, these transformations facilitate the use of V-RTC by enabling the efficient handling of signed data in a format that supports parallel vector operations, thereby enhancing the performance of image compression and decompression tasks.

As described above, the transformation in equation (2) does not preserve the symmetry between positive and negative values, but the compression loss is relatively small. Even though the mathematical definitions in equations (2) and (3) are in conditional form, the actual implementation can be done with only basic arithmetic and logic operations, and without conditional statements, as shown with the C implementation below, which can be easily converted to SIMD instructions.

```
unsigned signed_to_unsigned(int n)
{
  return (n << 1) \hat{ } (n >> 31);
}
int unsigned_to_signed(unsigned h)
{
  return (int(h) \hat{ } -int(h & 1)) >> 1;
}
```

The above code snippet includes two functions that perform transformations between signed and unsigned integers, which are used for efficient data processing in V-RTC.

The first function, unsigned signed_to_unsigned(int n), converts a signed integer n into an unsigned integer. The transformation is achieved using bitwise operations. Specifically, the expression (n<<1) shifts the bits of n one position to the left, effectively multiplying n by 2. The expression (n>>31) shifts the bits of n 31 positions to the right, which extracts the sign bit of n. The XOR operation \hat{ } combines these two results, ensuring that the transformation is consistent for both positive and negative values of n.

The second function, int unsigned_to_signed(unsigned h), performs the inverse transformation, converting an unsigned integer h back to a signed integer. The expression int(h)\hat{ }-int(h & 1) uses the bitwise AND operation & to check if h is odd or even. If h is odd, the result is adjusted by XORing with −1, effectively flipping the bits. The result is then right-shifted by one position using>>1, which divides the value by 2, completing the conversion back to a signed integer.

These transformations are designed to be efficient, using only basic arithmetic and logic operations, which can be easily implemented in parallel processing environments. This efficiency is useful for V-RTC, as it enables the handling of signed data in a format that supports parallel vector operations, thereby enhancing the performance of image compression and decompression tasks.

The next modification of V-RTC, relative to RTC, relates to how a pair of non-negative values is coded, given their maximum value. When coding integers, the coding of pairs of non-negative values can be decomposed into first using a ternary alphabet to represent the information on which values correspond to the maximum (first, second, or both), and if not both, followed by coding the value smaller than the maximum.

As explained above, such a process adds more operations and conditional execution that makes vector processing more complicated and slower. The proposed solution for V-RTC is to use another transformation, between pairs of non-negative values (i, j), exploiting the fact that given m=max(i, j), there are only 2m+1 possible cases, and thus the pair can be coded with a single number c∈{0, 1, . . . ,2m}.

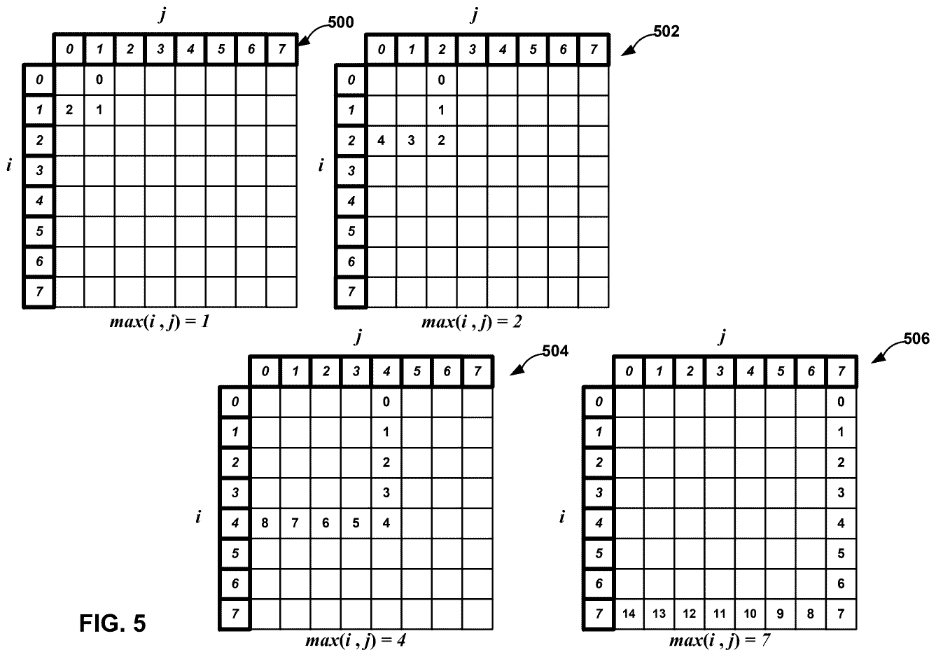

There are many options for creating such representation of pairs of non-negative numbers, and FIG. 5 shows some cases. For instance, if max(i, j)=1 then c∈{0,1,2}, and the mapping from c to i and j can follow the convention shown in FIG. 5.

FIG. 5 illustrates examples of how pairs of non-negative integers with a given maximum magnitude can be represented with symbols in a range 0, 1, . . . , 2 max(i, j). In the first example 500, where max(i, j)=1, the encoding scheme assigns a distinct code value to each possible pair of (i, j) combinations. The code values range from 0 to 2, covering all possible pairs within the given maximum value constraint. For example, a code value of 0 means that i is 0 and j is 1. A code value of 1 means that i is 1 and j is 1. A code value of 2 means that i is 1 and j is 0. The second example 502 demonstrates the encoding for max(i, j)=2. Here, the code values range from 0 to 5, representing all possible pairs of (i, j) that satisfy the maximum value condition. In the third example 504, the encoding is shown for max(i, j)=4. The code values extend from 0 to 12, covering a broader range of (i, j) pairs. This example highlights the scalability of the encoding method as the maximum value increases, allowing for more combinations to be represented with a single code value. The final example 506 illustrates the encoding for max (i, j)=7. The code values in this scenario range from 0 to 27, accommodating an even larger set of (i, j) pairs. This demonstrates the flexibility and efficiency of the encoding scheme in handling a wide range of maximum values, making the scheme suitable for various applications where compact data representation is important.

Generally, this transformation may be defined as follows:

$$m ( i , j ) = max ( i , j ) , \qquad ( 4 )$$

$$c ( i , j ] ) = \{ \begin{matrix}i , & i \leq j , \\ 2 i - j , & i \geq j ,\end{matrix}$$

The inverse transformation is defined by:

$$i ( m , c ) = \{ \begin{matrix}c , & c \leq m , \\ m , & c \geq m ,\end{matrix} , \qquad ( 5 )$$

$$j ( m , c ) = \{ \begin{matrix}m , & c \leq m , \\ 2 m - c , & c \geq m .\end{matrix}$$

Equation (4) defines a transformation used to encode pairs of non-negative integers (i,j) based on their maximum value. In this transformation, m(i,j) represents the maximum of the two integers i and j. The function c(i,j) assigns a single code value to the pair (i,j) based on their relative magnitudes. If i is less than or equal to j, the code value is simply i. If i is greater than j, the code value is calculated as 2i−j. This encoding scheme allows for a compact representation of the pair using a single integer, which is particularly useful in data compression applications.

Equation (5) provides the inverse transformation, which decodes the single code value c back into the original pair of integers (i,j) given the maximum value m. In this inverse transformation, the function i(m,c) determines the value of i based on the code value c and the maximum m. If c is less than or equal to m, i is equal to c. Otherwise, i is set to m. Similarly, the function j(m,c) calculates the value of j. If c is less than or equal to m, j is equal to m. If c is greater than m, j is computed as 2m−c. This inverse transformation allows for the recovery of the original pair of integers from the encoded value, ensuring that the data can be accurately reconstructed.

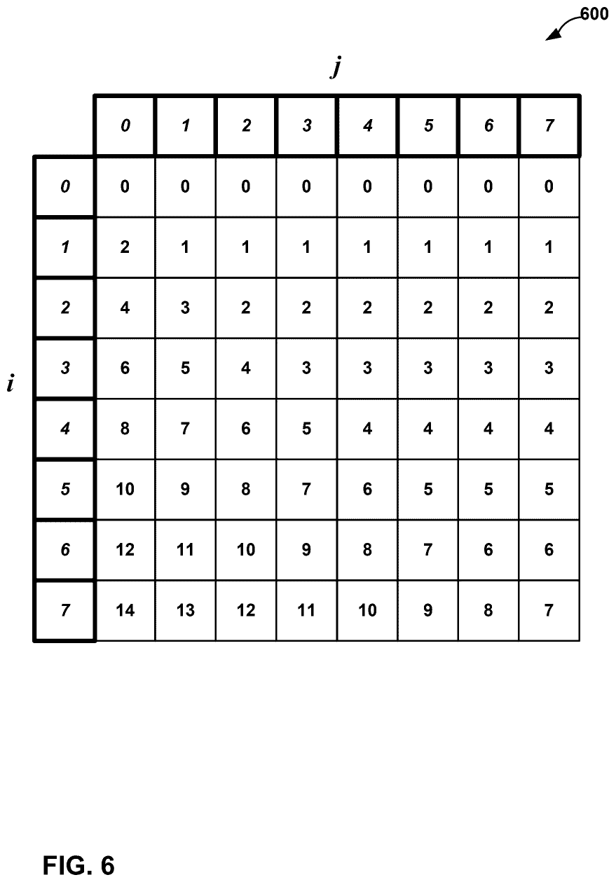

We can observe from the examples in FIG. 5 that 0≤c(i, j)≤2m(i, j), and that given m from a node in the range tree of FIG. 4, then c can uniquely identify the values in the two direct descendant nodes. FIG. 6 illustrates an example array of values from the transformation function in equation (4). FIG. 6 demonstrates how pairs of integers are mapped to a single code value based on their maximum value, m=max(i, j), for maximum values ranging from 0 to 7. In array 600, the rows are indexed by the integer i and the columns by the integer j. Each cell in array 600 contains a code value that represents the pair (i, j). The transformation function c(i, j) is used to assign a distinct code to each pair, which is particularly useful for data compression applications. The function is defined such that if i≤j, the code value is i, and if i>j, the code value is 2i−j. Array 600 effectively illustrates the compact representation of pairs of integers generated by the V-RTC techniques described herein. This encoding scheme allows for efficient compression by reducing the number of bits required to represent data, particularly when the data values are closely grouped. FIG. 6 highlights the scalability of the encoding method as the maximum value increases, allowing for more combinations to be represented with a single code value. This approach is advantageous in scenarios where compact data representation is important, such as in high-throughput image processing applications.

In view of the foregoing, in a first broad example of the disclosure, computing device 100 may be configured to perform for data decompression, including the decompression of image data. Computing device 100 may be configured to retrieve a plurality of encoded image blocks from the memory, each encoded image block comprising encoded vectors, entropy decode, using parallel vector operations, the encoded vectors using V-RTC to generate decoded data, and reconstruct the decoded data into image blocks. In one example, the parallel vector operations are Single-Instruction-Multiple-Data (SIMD) operations or Single-Instruction-Multiple-Thread (SIMT) operations. Computing device 100 may be further configured to reconstruct images from the image blocks, and use the images as training data for a neural network.

In one example, to entropy decode, using parallel vector operations, the encoded vectors using V-RTC to generate the decoded data, computing device 100 may be configured to decode pairs of unsigned integers in the encoded vectors by traversing a range-tree structure to generate unsigned integers, wherein each node of the range-tree structure is associated with a maximum magnitude of a respective node, and convert the unsigned integers to signed integers using a transformation that maps each unique unsigned integer to a unique signed integer.

In one example of the disclosure, the encoded vectors are encoded transform coefficients, and the decoded data are decoded transform coefficients. In this example, to reconstruct the decoded data into image blocks, computing device 100 is further configured to apply an inverse transform to the decoded transform coefficients to form pixel data, and reconstruct the image blocks from the pixel data.

Likewise, for compression, computing device 100 may be configured to generate a plurality of image blocks from images stored in the memory, each image block comprising vectors, entropy encode, using parallel vector operations, the vectors using vector-range tree coding (V-RTC) to generate encoded data, and store the encoded data in the memory. In one example, the parallel vector operations are Single-Instruction-Multiple-Data (SIMD) operations or Single-Instruction-Multiple-Thread (SIMT) operations.

In one example, to entropy encode, using parallel vector operations, the vectors using V-RTC to generate the encoded data, computing device 100 may be configured to convert signed integers in the vectors to unsigned integers using a transformation that maps each signed integer to a unique unsigned integer, and encode pair of unsigned integers in the vectors by traversing a range-tree structure to generate the encoded data, wherein each node of the range-tree structure is associated with a maximum magnitude of a respective node.

In one example, the vectors are transform coefficients. In this example, computing device 100 may be further configured to apply a transform to pixel data of the image blocks to generate the transform coefficients.

In another example, aspects of the above approach for coding pairs of unsigned integers can also be used to eliminate the need for using the signed-to-unsigned integer conversion described above. In this case, the mathematical property to be exploited is that if m=max(|i|, |j|), then there are only 8m possible cases, and thus the pair (i, j) can be coded with a single number c∈{0, 1, . . . , 8m−1}. In this example, an implementation of V-RTC may be modified to process unsigned integer magnitudes in the parent nodes of the range tree, and signed integers only on the leaf nodes.

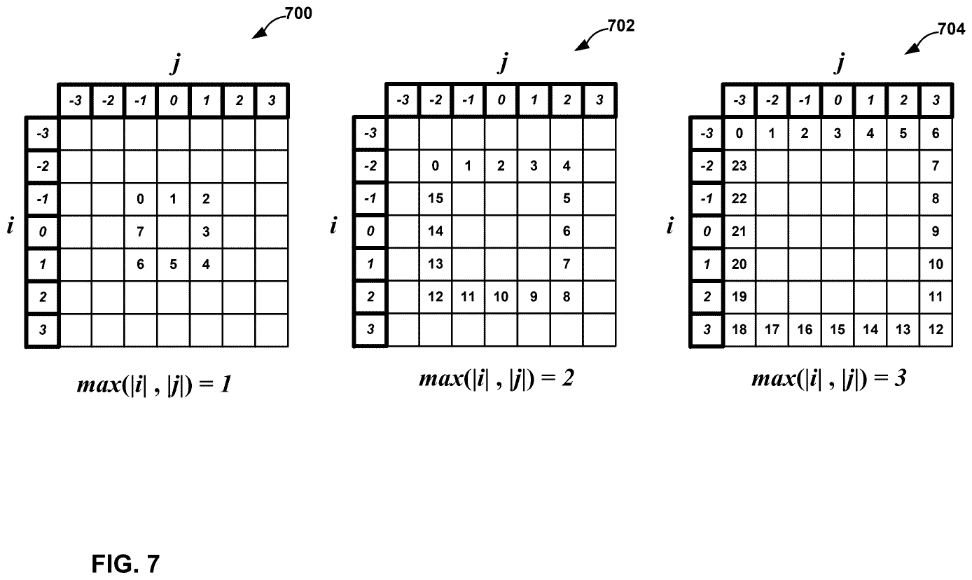

For example, in the case where max(|i|, |j|)=1, the pair of signed integers (i, j) can be coded with a single number c∈{0, 1, . . . , 7}, using an assignment as shown in example 700 of FIG. 7. FIG. 7 also shows how the idea can be extended to larger maximum magnitude values.

FIG. 7 illustrates examples of how pairs of signed integers with a given maximum magnitude can be represented with symbols in range 0, 1, . . . , 8 max(|i|,|j|)−1. In example 700, where max(∥i∥,∥j∥)=1, the encoding scheme assigns a distinct code value to each possible pair of (i, j) combinations between −1 and 1. The code values range from 0 to 7, covering all possible pairs within the given maximum value constraint. Example 702 demonstrates the encoding for max(∥i∥,∥j∥)=2. Here, the code values range from 0 to 23, representing all possible pairs of (i, j) between −2 and 2 that satisfy the maximum value condition. This example highlights the scalability of the encoding method as the maximum value increases, allowing for more combinations to be represented with a single code value. Example 704 illustrates the encoding for max(∥i∥, ∥j∥)=3. The code values in this scenario range from 0 to 47, accommodating an even larger set of (i, j) pairs between −3 and 3. This demonstrates the flexibility and efficiency of the encoding scheme in handling a wide range of maximum values, making the scheme suitable for various applications where compact data representation is important.

The assignment between single code values and pairs is not distinct and is a convention that needs to be shared by the encoder and decoder. This encoding scheme allows for efficient compression by reducing the number of bits required to represent data, particularly when the data values are closely grouped. The approach is advantageous in scenarios where compact data representation is important, such as in high-throughput image processing applications.

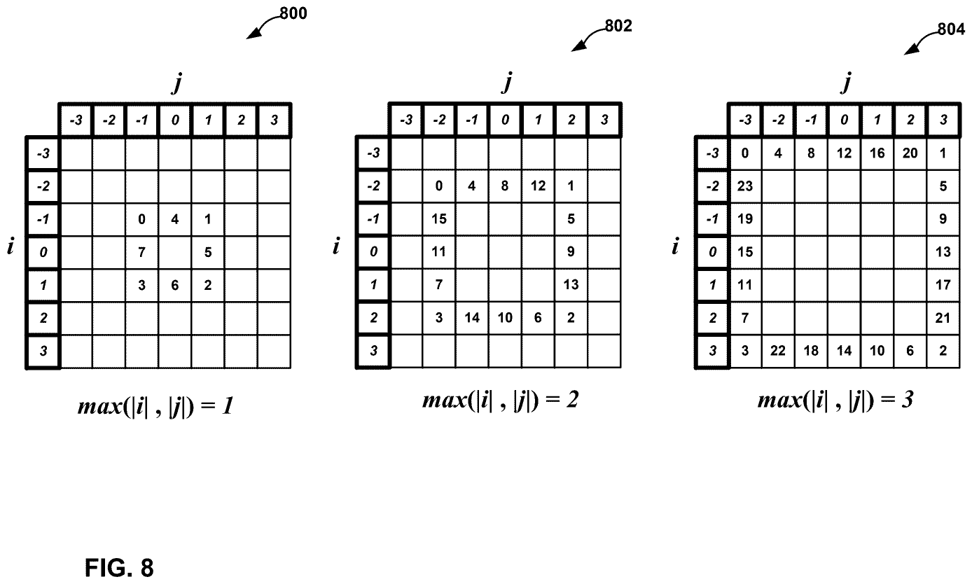

The assignment between single code values and pairs is not unique. That is, the code values used may take on different numbers or generated with slightly different equations. As such, the methods used to perform the transformations between code values and pairs of integers is a convention that needs to be shared by both a V-RTC encoder and a V-RTC decoder. For example, FIG. 8 shows an alternative numbering, different from the one used in FIG. 8, which is less intuitive, but can be more efficiently implemented using SIMD instructions. In FIG. 8, example 800 is for a maximum value of 1, example 802 is for a maximum value of 2, and example 804 is for a maximum value of 3. The example of FIG. 8 uses the two least significant bits to indicate the “square side” and the index divided by four represents the value.

For parallel computation it is again preferable to implement those transformations without conditional execution. This can be done using predicate coding, i.e., both possible function values are computed, and then the correct value is selected using a binary mask defined by a certain condition. In the C programming language this corresponds to:

$$mask = ( condition ? \sim 0 : 0 ) ;$$

$$result = ( value\_ 1 \& mask ) \vert ( value\_ 2 \& \sim mask ) ;$$

The code snippet above selects between two values based on a condition, often referred to as “predicate coding” or “conditional selection.” A description of how the code works is below:
1. Mask Creation:
   mask=(condition? ~0:0);
   This line uses a ternary conditional operator to create a mask based on a given condition. If the condition is true, the mask is set to ~0, which is a bitwise NOT operation on 0, resulting in a mask with all bits set to 1 (i.e., 0xFFFFFFFF in a 32-bit system). If the condition is false, the mask is set to 0, with all bits set to 0.
2. Result Calculation:
   result=(value_1 & mask)|(value_2 & ~mask);
   This line calculates the result by using bitwise operations to select between value_1 and value_2.
   (value_1 & mask): This operation retains the bits of value_1 where the mask has bits set to 1, effectively selecting value_1 when the condition is true.
   (value_2 & ~mask): This operation retains the bits of value_2 where the mask has bits set to 0, effectively selecting value_2 when the condition is false.
   The bitwise OR operation|combines the results of the two previous operations, resulting in the final value being either value_1 or value_2 based on the condition.

This technique is efficient for selecting between two values without using explicit conditional statements like if-else, making it suitable for scenarios where conditional execution needs to be minimized, such as in parallel processing or SIMD (Single-Instruction-Multiple-Data) operations. It allows for the execution of both potential outcomes and then uses the mask to select the appropriate result, which can be advantageous in certain computational environments.

There are SIMD instructions specifically for computing the mask and predicate combination. However, their format depends on the computing platform. For this reason, C language is used to represent the method, but with the assumption instead of being applied to single numbers, code operations are applied to all elements in a D-dimensional vector.

In view of the foregoing, in a second broad example of the disclosure, computing device 100 may be configured to perform for data decompression, including the decompression of image data. Computing device 100 may be configured to retrieve a plurality of encoded image blocks from the memory, each encoded image block comprising encoded vectors, entropy decode, using parallel vector operations, the encoded vectors using V-RTC to generate decoded data, and reconstruct the decoded data into image blocks. In one example, the parallel vector operations are Single-Instruction-Multiple-Data (SIMD) operations or Single-Instruction-Multiple-Thread (SIMT) operations. Computing device 100 may be further configured to reconstruct images from the image blocks, and use the images as training data for a neural network.

In one example, to entropy decode, using parallel vector operations, the encoded vectors using V-RTC to generate the decoded data, computing device 100 may be configured to decode pairs of signed integers in the encoded vectors by traversing leaf nodes of a range-tree structure to generate signed integers, wherein each leaf node of the range-tree structure is associated with a maximum magnitude of a respective leaf node, decode pairs of unsigned integers in the encoded vectors at parent nodes of the range-tree structure to generate unsigned integers, wherein each parent node of the range-tree structure is associated with the maximum magnitude of a respective parent node, and convert the unsigned integers to signed integers using a transformation that maps each unique unsigned integer to a unique signed integer.

In one example of the disclosure, the encoded vectors are encoded transform coefficients, and the decoded data are decoded transform coefficients. In this example, to reconstruct the decoded data into image blocks, computing device 100 is further configured to apply an inverse transform to the decoded transform coefficients to form pixel data, and reconstruct the image blocks from the pixel data.

Likewise, for compression, computing device 100 may be configured to generate a plurality of image blocks from images stored in the memory, each image block comprising vectors, entropy encode, using parallel vector operations, the vectors using vector-range tree coding (V-RTC) to generate encoded data, and store the encoded data in the memory. In one example, the parallel vector operations are Single-Instruction-Multiple-Data (SIMD) operations or Single-Instruction-Multiple-Thread (SIMT) operations.

In one example, to entropy encode, using parallel vector operations, the vectors using V-RTC to generate the encoded data, computing device 100 may be configured to convert signed integers to unsigned integers at parent nodes of a range-tree structure, encode pairs of unsigned integers in the vectors at the parent nodes of the range-tree structure to generate the encoded data, wherein each parent node of the range-tree structure is associated with the maximum magnitude of a respective parent node, and encode pairs of signed integers in the vectors by traversing leaf nodes of the range-tree structure to generate the encoded data, wherein each leaf node of the range-tree structure is associated with a maximum magnitude of a respective leaf node.

In one example, the vectors are transform coefficients. In this example, computing device 100 may be further configured to apply a transform to pixel data of the image blocks to generate the transform coefficients.

Using that “pseudo-C language” convention, the function for V-RTC encoding and decoding are shown below. Like the original RTC method, the implementation exploits the compact representation of a binary tree in a single array. In fact, while FIG. 4 shows an example of a complete tree, the array dimension does not have to be a power for two for those functions to work correctly.

V-RTC Encoding (Vector operations represent SIMD instructions)

```
void V_RTC_encoder(int array_dim,
        int_vector value_array[ ],
        unsigned_vector range_tree[ ],
        unsigned_vector code_array[ ])
  {
    // conversion of signed to unsigned integer vectors
    for (int k = 0; k < array_dim; ++k)
      range_tree[k+array_dim] =
      signed_to_unsigned(value_array[k]);
    // computation of tree with ranges and corresponding codes
    unsigned_vector val1, val2, mask, maxv, altc;
    for (int k = array_dim − 1; k >= 1; --k) {
      val1 = range_tree[2*k];
      val2 = range_tree[2*k+1];
      mask = (val1 > val2 ? ~0 : 0);
      maxv = (val1 & mask) | (val2 & ~mask);
      altc = (maxv << 1) − val2;
      range_tree[k] = maxv;
      code_array[k] = (altc & mask) | (val1 & ~mask);
    }
  code_array[0] = range_tree[1];
    // encode first vector using universal integer code
    universal_encode(range_tree[1]);
    // binary encoding of range-bounded vector pairs
    for (int k = 1; k < array_dim; ++k)
      range_encode(code_array[k], 2 * range_tree[k] + 1);
  }
```

The code snippet above is a function named V_RTC_encoder that implements the V-RTC encoding process. This function is designed to convert signed integer vectors into a compressed format using a range-tree structure. A detailed explanation of the code is below:
1. Function Definition:
   The function V_RTC_encoder takes four parameters: array_dim, value_array[ ], range_tree[ ], and code_array[ ].
   array_dim represents the dimension of the array.
   value_array[ ] is an array of signed integer vectors that need to be encoded.
   range_tree[ ] and code_array[ ] are arrays used to store intermediate and final encoded values.
2. Conversion of Signed to Unsigned Integer Vectors:
   The function begins by converting each signed integer in value_array[ ] to an unsigned integer using the signed_to_unsigned function.
   This conversion is stored in the range_tree[ ] array starting from the index array_dim.
3. Computation of Tree with Ranges and Corresponding Codes:
   The function declares several unsigned vector variables: val1, val2, mask, maxv, and altc.
   The function then iterates over the range_tree[ ] array in reverse order, starting from array_dim−1 down to 1.
   For each iteration, it retrieves two values, val1 and val2, from the range_tree[ ] array.
   A mask is created based on the comparison of val1 and val2. If val1 is greater than val2, the mask is set to all bits as 1; otherwise, it is set to 0.
   The maximum value maxv is computed using the mask to select between val1 and val2.
   An alternative code altc is calculated by left-shifting maxv by one and subtracting val2.
   The range_tree[ ] and code_array[ ] arrays are updated with maxv and the selected code value, respectively.
4. Encoding the First Vector:
   The first element of code_array[ ] is set to the first element of range_tree[ ].
   The function then encodes the first vector using a universal integer coding method, universal_encode, applied to range_tree[1].
5. Binary Encoding of Range-Bounded Vector Pairs:
   Finally, the function iterates over the code_array[ ] from index 1 to array_dim, encoding each element using the range_encode function.
   The encoding is performed with a range defined by 2*range_tree[k]+1.

Overall, this function encodes signed integer vectors into a compressed format using a range-tree structure, leveraging the capabilities of V-RTC to achieve high compression efficiency.

V-RTC Decoding (Vector operations represent SIMD instructions)

```
void V_RTC_decoder(int array_dim,
        unsigned_vector range_tree[ ],
        int_vector value_array[ ])
  {
    // decode first vector using universal integer code
    range_tree[1] = universal_decode( );
    // binary decoding of range-bounded vector pairs
    // combined with tree recovery
    unsigned_vector mask, maxv, altc, code;
    for (int k = 1; k < array_dim; ++k) {
      maxv = range_tree[k];
      code = range_decode(2 * range_tree[k] + 1);
      mask = (code > maxv ? ~0 : 0);
      altc = (maxv << 1) − code;
      range_tree[2*k] = (maxv & mask) | (code & ~mask);
      range_tree[2*k+1] = (altc & mask) | (maxv & ~mask);
    }
    // conversion of unsigned to signed integer vectors
    for (int k = 0; k < array_dim; ++k)
      value_array[k] =
      unsigned_to_signed(range_tree[k+array_dim]);
  }
```

The code snippet above is a function named is a function named V_RTC_decoder that implements the Vector-Range Tree Coding (V-RTC) decoding process. This function is designed to convert encoded data back into its original signed integer vector format using a range-tree structure. A detailed explanation is below:
1. Function Definition:
   The function V_RTC_decoder takes three parameters: array_dim, range_tree[ ], and value_array[ ].
   array_dim represents the dimension of the array.
   range_tree[ ] is an array containing the encoded data that needs to be decoded.
   value_array[ ] is an array used to store the final decoded signed integer vectors.
2. Decoding the First Vector:
   The function begins by decoding the first vector using a universal integer coding method, universal_decode, which is applied to range_tree[1].
3. Binary Decoding of Range-Bounded Vector Pairs and Tree Recovery:
   The function declares several unsigned vector variables: mask, maxv, altc, and code.
   The function then iterates over the range_tree[ ] array from index 1 to array_dim.
   For each iteration, the function retrieves the maximum value maxv from the range_tree[ ] array.
   The range_decode function is used to decode the code value with a range defined by 2*range_tree[k]+1.
   A mask is created based on the comparison of code and maxv. If code is greater than maxv, the mask is set to all bits as 1; otherwise, it is set to 0.
   An alternative code altc is calculated by left-shifting maxv by one and subtracting code.
   The range_tree[ ] array is updated with the decoded values using the mask to select between maxv and code, and between altc and maxv.
4. Conversion of Unsigned to Signed Integer Vectors:
   Finally, the function iterates over the range_tree[ ] array from index 0 to array_dim.
   The function converts each unsigned integer in range_tree[ ] back to a signed integer using the unsigned_to_signed function and stores the result in value_array[ ].

Overall, this function efficiently decodes the compressed data back into its original signed integer vector format using a range-tree structure, leveraging the capabilities of V-RTC to achieve accurate and efficient data reconstruction.

In the code above for V-RTC encoding and V-RTC decoding, the functions for signed to unsigned integer conversions are simply the functions described above converted to vector transformations. The functions, universal_encode and universal_decode, are meant for initialization only, and thus do not affect performance significantly, and can be implemented sequentially with a universal integer coding method like the Elias delta code.

Functions for V-RTC Parallel Entropy Coding

```
unsigned_vector floor_log2(unsigned_vector range)
{
  unsigned_vector log2 = unsigned_vector(0);
  unsigned_vector bitp = unsigned_vector(8);
  unsigned_vector temp = range;
  unsigned_vector mask, adds;
  for (int i = 0; i < 4; i++) {
    mask = ((temp >> bitp) == 0 ? 0 : ~0);
    adds = mask & bitp;
    log2 += adds;
    temp >>= adds;
    bitp >>= 1;
  }
  return log2;
}
void range_encode (unsigned_vector data,
        unsigned_vector range)
{
  unsigned_vector bits = floor_log2(range);
  unsigned_vector tops = (2 << bits) − range;
  unsigned_vector mask = (data >= tops ? ~0 : 0);
  unsigned_vector code = data + (tops & mask);
  bits −= mask;
  save_bits(code, bits);
}
unsigned_vector range_decode (unsigned_vector range)
{
  unsigned_vector bits = floor_log2(range);
  unsigned_vector tops = (2 << bits) − range;
  unsigned_vector code = peek_bits(bits + 1);
  unsigned_vector data = code >> 1;
  unsigned_vector mask = (data >= tops ? ~0 : 0);
  data = (data & ~mask) | ((code − tops) & mask);
  bits -= mask;
  discard_bits(bits);
  return data;
}
```

The code snippet above includes three functions that are part of the V-RTC process, specifically focusing on calculating logarithms, encoding, and decoding operations for bounded integer values.
1. floor_log 2 Function:
   This function calculates the floor of the base-2 logarithm of each element in an unsigned vector range.
   The function initializes log 2 to zero and bitp to eight, representing the bit position.
   The function iterates four times, each time checking if the current temp value right-shifted by bitp is zero. If not, it sets mask to all bits as 1; otherwise, it sets mask to 0.
   The adds variable is calculated by ANDing mask with bitp, and this value is added to log 2.
   The temp value is right-shifted by adds, and bitp is right-shifted by one.
   The function returns the calculated log 2 value, which represents the floor of the base-2 logarithm for each element in the vector.
2. range_encode Function:
   This function encodes an unsigned vector data within a specified range.
   This function first calculates the number of bits required for encoding using the floor_log 2 function.
   The tops variable is calculated as (2<<bits)−range, representing the top boundary for encoding.
   A mask is created to determine if data is greater than or equal to tops. If true, mask is set to all bits as 1; otherwise, it is set to 0.
   The code is calculated by adding data to tops ANDed with mask.
   The number of bits is adjusted by subtracting mask, and the code is saved using the save_bits function.
3. range_decode Function:
   This function decodes an unsigned vector within a specified range.
   This function calculates the number of bits required for decoding using the floor_log 2 function.
   The tops variable is calculated similarly to the range_encode function.
   The code is retrieved using the peek_bits function, which reads the specified number of bits plus one.
   The data is initially set to code right-shifted by one.
   A mask is created to determine if data is greater than or equal to tops. If true, mask is set to all bits as 1; otherwise, it is set to 0.
   The data is adjusted using the mask to select between data and code-tops.
   The number of bits is adjusted by subtracting mask, and the used bits are discarded using the discard_bits function.
   The function returns the decoded data.

The functions range_encode and range_decode are used for binary coding and. They use the same simple entropy coding of RTC and are based on the fact that a bounded integer 0≤a<b can be coded with [log₂ b] or [log₂ b] bits, depending on the value of a. However, the functions in the V-RTC parallel entropy coding shown above use predicate programming for parallel execution in vectors.

The functions in the V-RTC parallel entropy coding shown above include the function save_bits, which simply saves each data element in a vector using the corresponding number of bits in a vector parameter. The function peek_bits is used to read data with an upper bound on the number of bits, using the data read to determine the final result and number of bits, and then discard_bits is used to indicate that final number.

The techniques of this disclosure were tested using SIMD instructions and 512-bit vector registers, which correspond to 8×32-bit integer vectors. For comparisons to the JPEG standard, V-RTC was tested to also compress 8×8 DCT coefficients.

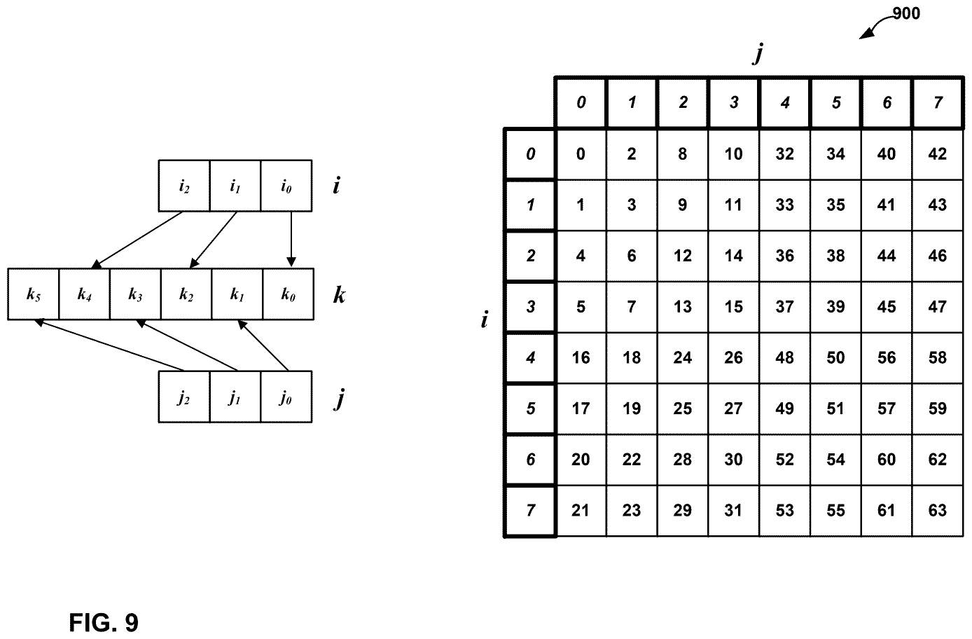

One modification is that V-RTC does not use the zigzag scan order of JPEG for transform coefficients, which is meant for an early scan termination that is not used. Instead, the V-RTC tree can be created using a “recursive zigzag” coefficient scanning order, as shown in FIG. 9, which is defined by interleaving the bits in the vertical and horizontal indexes. It was observed that this is not critical for obtaining good results, and that row and column scans yielded similar results.

FIG. 9 illustrates an example scan order for 8×8 transform coefficients. FIG. 9 demonstrates the arrangement and indexing of coefficients in a matrix format. Matrix 900 includes indices i and j representing the row and column positions of the transform coefficients. The matrix is organized in a specific order that facilitates efficient processing and compression. The indices are arranged in a manner that allows for a recursive zigzag scanning pattern, which is defined by interleaving the bits in the vertical and horizontal indexes. This pattern plays better optimizes the compression process by ensuring that the coefficients are accessed in a sequence that maximizes data locality and minimizes memory access times.

The left part of FIG. 9 provides a conceptual representation of the recursive zigzag scanning order. The illustration shows how the indices i, j, and k are interleaved to form a distinct scan path through the matrix. This interleaving is achieved by combining the bits of the indices in a specific manner, which is depicted by the arrows connecting the index blocks. This approach ensures that the scanning order is both efficient and adaptable to different matrix sizes, making the method suitable for high-throughput image processing applications.

The process of organizing pixel values into the vectors that are compressed with V-RTC should be designed to simplify the parallelization process and depends on the processor and vector sizes. In the experiments and performance tests the image pixels were reorganized using blocks for DCT transformation, that were grouped in larger blocks that we call tiles.

In general, an image with dimension Dₓ×D_{y} is divided into Tₓ×T_{y} tiles, each tile with Bₓ×B_{y} blocks, and each block with Pₓ×P_{y} pixels. It is assumed that the tiles cover all the image, i.e.,

$${D}_{x} \leq {T}_{x} {B}_{x} {P}_{x} , \qquad ( 6 )$$

$${D}_{y} \leq {T}_{y} {B}_{y} {P}_{y} ,$$

Some form of padding is used when the image sizes are not multiples of tile sizes.

Defining (tₓ, t_{y}), (bₓ, b_{y}), and (pₓ, P_{y}) as, respectively, the pairs of indexes of tiles, blocks and pixels, the pixel coordinates are defined as:

$$x = {p}_{x} + {P}_{x} ( {b}_{x} + {B}_{x} {t}_{x} ) , \qquad ( 7 )$$

$$y = {p}_{y} + {P}_{y} ( {b}_{y} + {B}_{y} {t}_{y} ) .$$

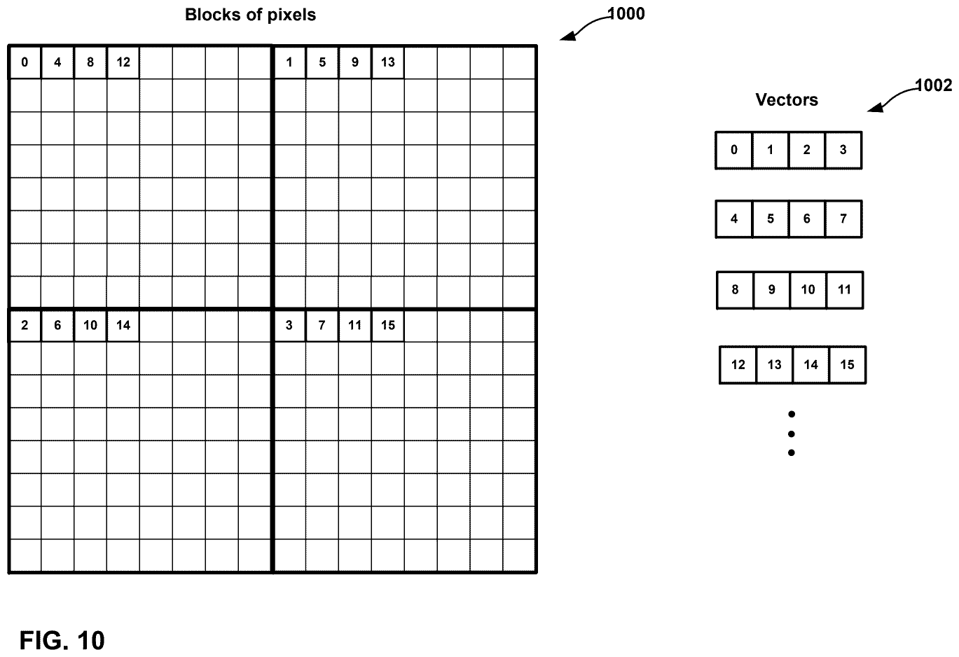

Within each tile an array of Pₓ×P_{y} vectors vₚ_{ₓ}_{,p}_{_{y}}, each with dimension BₓB_{y}, are defined by rearranging elements from each block for SIMD computations, as shown in the example of FIG. 10. FIG. 10 illustrates an example of how pixel data is organized into vectors for processing. FIG. 10 includes block of pixels 1000 and vectors 1002. Block of pixels1000 represents a grid of pixel data, which is divided into smaller segments for processing. Each block within block of pixels 1000 contains a specific arrangement of pixel values. Vectors 1002 are derived from the pixel data in block of pixels 1000. Each vector corresponds to a specific set of pixel values, organized in a manner that optimizes the use of parallel processing capabilities. The transformation of pixel data into vectors enables the application of vector-based operations, such as those used in the V-RTC method, enhancing the efficiency and speed of image processing tasks.

The original pixel line scan order within each tile is:

$${s}_{orig} ( {p}_{x} , {p}_{y} , {b}_{x} , {b}_{y} ) = {p}_{x} + {P}_{x} ( {b}_{x} + {B}_{x} ( {p}_{y} + {P}_{y} {b}_{y} ) ) , \qquad ( 8 )$$

which is converted to the vector scan order:

$${s}_{vector} ( {p}_{x} , {p}_{y} , {b}_{x} , {b}_{y} ) = {b}_{x} + {B}_{x} ( {b}_{y} + {B}_{y} ( {p}_{x} + {P}_{x} {p}_{y} ) ) . \qquad ( 9 )$$

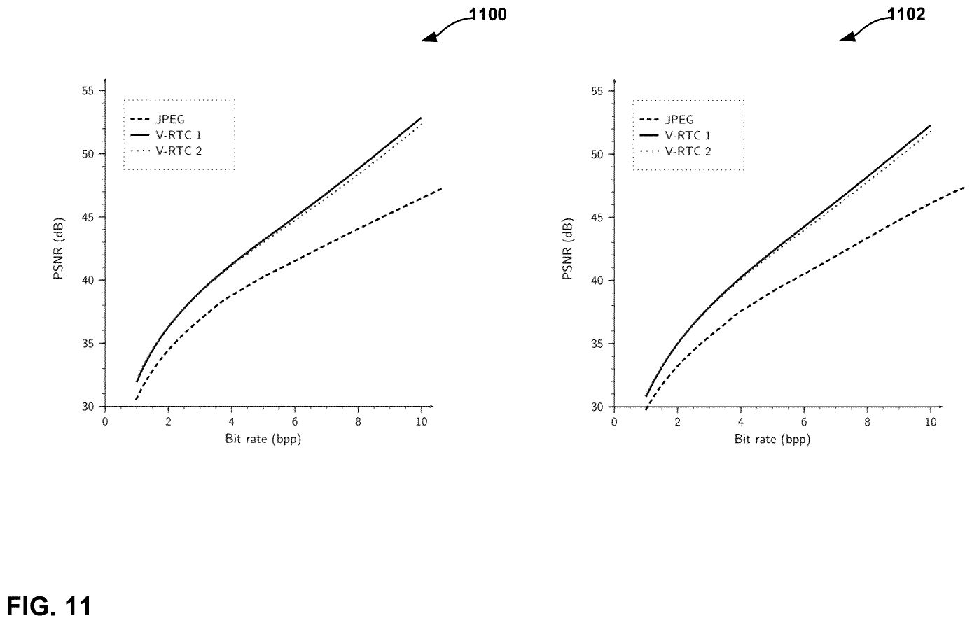

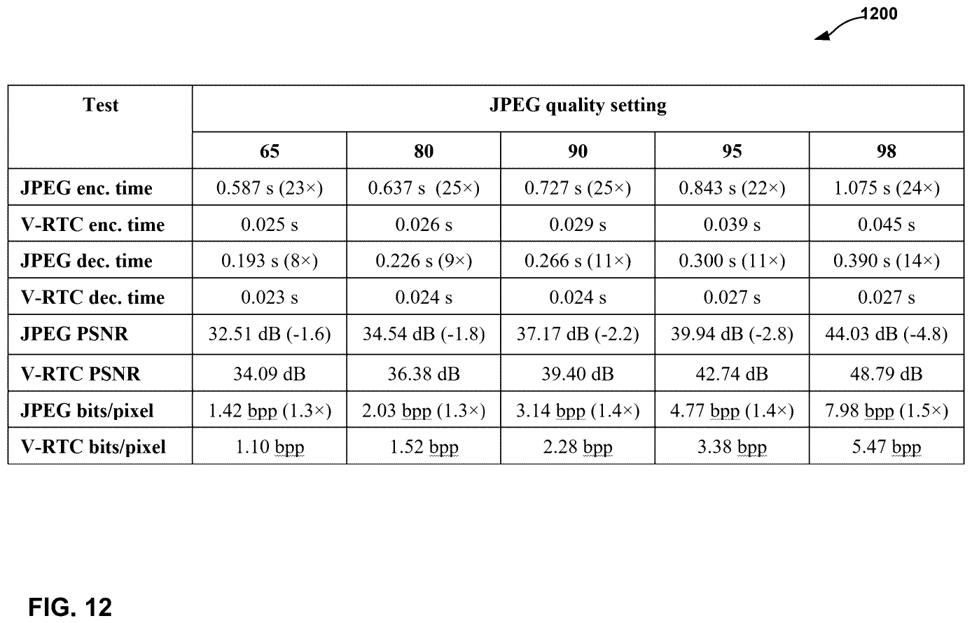

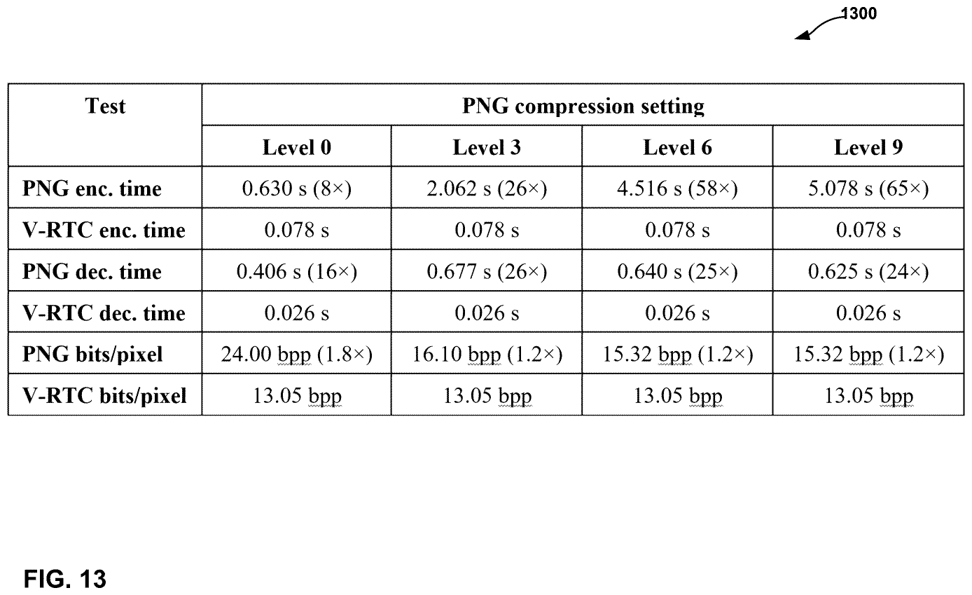

Two version of V-RTC were implemented and together with JPEG were used to compress two sets of ISO test images, each set with 4 images of dimension 2560×2048. The average results are shown in FIG. 11, where V-RTC 1 is a version using the signed-to-unsigned conversions, while V-RTC 2 implements the mapping on signed integers at tree leaves. FIG. 11 illustrates example rate-distortion test results. FIG. 12 illustrates example test results for lossy image compression compared to JPEG. FIG. 13 illustrates example test results for lossy image compression compared to PNG.

In FIGS. 11-13, it can be observed that even though V-RTC uses simple coding, the compression results are significantly better than JPEG's, with 28% BD-rate reduction in combined RGB.

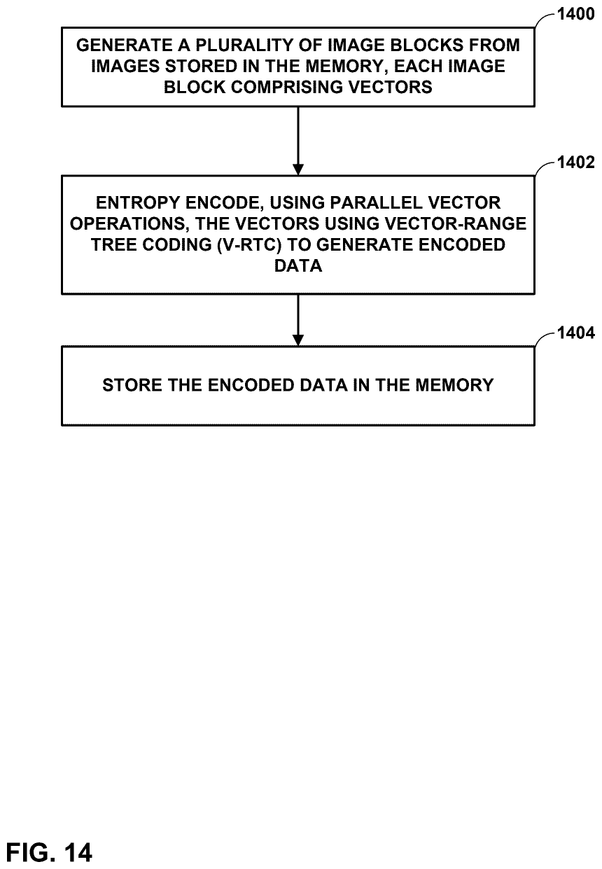

FIG. 14 is a block diagram illustrating an example compression process of the disclosure. The techniques of FIG. 14 may be performed by processing circuitry of computing device 100.

In one example, computing device 100 may generate a plurality of image blocks from images stored in the memory, each image block comprising vectors (1400). Computing device may further entropy encode, using parallel vector operations, the vectors using vector-range tree coding (V-RTC) to generate encoded data (1402), and store the encoded data in the memory (1404). In one example, the parallel vector operations are Single-Instruction-Multiple-Data (SIMD) operations or Single-Instruction-Multiple-Thread (SIMT) operations.

In one example, to entropy encode, using parallel vector operations, the vectors using V-RTC to generate the encoded data, computing device 100 is configured to convert signed integers in the vectors to unsigned integers using a transformation that maps each signed integer to a unique unsigned integer, and encode pair of unsigned integers in the vectors by traversing a range-tree structure to generate the encoded data, wherein each node of the range-tree structure is associated with a maximum magnitude of a respective node.

In another example, to entropy encode, using parallel vector operations, the vectors using V-RTC to generate the encoded data, computing device 100is configured to convert signed integers to unsigned integers at parent nodes of a range-tree structure, encode pairs of unsigned integers in the vectors at the parent nodes of the range-tree structure to generate the encoded data, wherein each parent node of the range-tree structure is associated with the maximum magnitude of a respective parent node, and encode pairs of signed integers in the vectors by traversing leaf nodes of the range-tree structure to generate the encoded data, wherein each leaf node of the range-tree structure is associated with a maximum magnitude of a respective leaf node.

In one example, the vectors are transform coefficients. In this example, computing device 100 may be configured to apply a transform to pixel data of the image blocks to generate the transform coefficients.

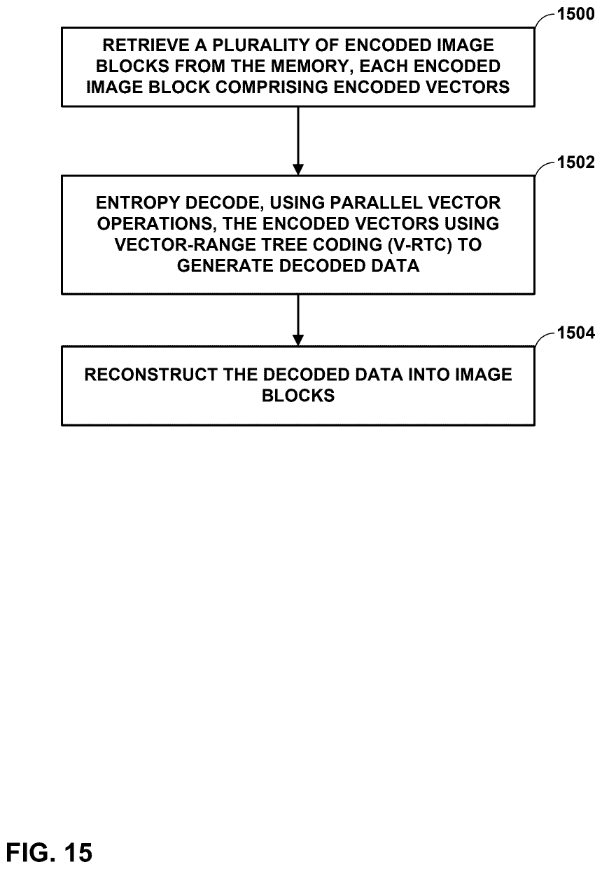

FIG. 15 is a block diagram illustrating an example decompression process of the disclosure. The techniques of FIG. 15 may be performed by processing circuitry of computing device 100.

In one example, computing device 100 may be configured to retrieve a plurality of encoded image blocks from the memory, each encoded image block comprising encoded vectors (1500). Computing device 100 may be further configured to entropy decode, using parallel vector operations, the encoded vectors using vector-range tree coding (V-RTC) to generate decoded data, and reconstruct the decoded data into image blocks. In one example, the parallel vector operations are Single-Instruction-Multiple-Data (SIMD) operations or Single-Instruction-Multiple-Thread (SIMT) operations.

In a further example, computing device 100 is further configured to reconstruct images from the image blocks, and use the images as training data for a neural network.

In one example, to entropy decode, using parallel vector operations, the encoded vectors using V-RTC to generate the decoded data, computing device 100 is configured to decode pairs of unsigned integers in the encoded vectors by traversing a range-tree structure to generate unsigned integers, wherein each node of the range-tree structure is associated with a maximum magnitude of a respective node, and convert the unsigned integers to signed integers using a transformation that maps each unique unsigned integer to a unique signed integer.

In another example, to entropy decode, using parallel vector operations, the encoded vectors using V-RTC to generate the decoded data, computing device 100 is configured to decode pairs of signed integers in the encoded vectors by traversing leaf nodes of a range-tree structure to generate signed integers, wherein each leaf node of the range-tree structure is associated with a maximum magnitude of a respective leaf node, decode pairs of unsigned integers in the encoded vectors at parent nodes of the range-tree structure to generate unsigned integers, wherein each parent node of the range-tree structure is associated with the maximum magnitude of a respective parent node, and convert the unsigned integers to signed integers using a transformation that maps each unique unsigned integer to a unique signed integer.

In another example, the encoded vectors are encoded transform coefficients, and the decoded data are decoded transform coefficients. In this example, to reconstruct the decoded data into image blocks, computing device 100 is further configured to apply an inverse transform to the decoded transform coefficients to form pixel data, and reconstruct the image blocks from the pixel data.

Aspects of the techniques of this disclosure include the following clauses.

Aspect 1. An apparatus for image decompression, the apparatus comprising: at least one memory; and processing circuitry in communication with the at least one memory, the processing circuitry configured to: retrieve a plurality of encoded image blocks from the memory, each encoded image block comprising encoded vectors; entropy decode, using parallel vector operations, the encoded vectors using vector-range tree coding (V-RTC) to generate decoded data; and reconstruct the decoded data into image blocks.

Aspect 2. The apparatus of Aspect 1, wherein to entropy decode, using parallel vector operations, the encoded vectors using V-RTC to generate the decoded data, the processing circuitry is configured to: decode pairs of unsigned integers in the encoded vectors by traversing a range-tree structure to generate unsigned integers, wherein each node of the range-tree structure is associated with a maximum magnitude of a respective node; and convert the unsigned integers to signed integers using a transformation that maps each unique unsigned integer to a unique signed integer.

Aspect 3. The apparatus of Aspect 1, wherein to entropy decode, using parallel vector operations, the encoded vectors using V-RTC to generate the decoded data, the processing circuitry is configured to: decode pairs of signed integers in the encoded vectors by traversing leaf nodes of a range-tree structure to generate signed integers, wherein each leaf node of the range-tree structure is associated with a maximum magnitude of a respective leaf node; decode pairs of unsigned integers in the encoded vectors at parent nodes of the range-tree structure to generate unsigned integers, wherein each parent node of the range-tree structure is associated with the maximum magnitude of a respective parent node; and convert the unsigned integers to signed integers using a transformation that maps each unique unsigned integer to a unique signed integer.

Aspect 4. The apparatus of any of Aspects 1-3, wherein the processing circuitry is further configured to: reconstruct images from the image blocks; and use the images as training data for a neural network.

Aspect 5. The apparatus of any of Aspects 1-4, wherein the encoded vectors are encoded transform coefficients, and wherein the decoded data are decoded transform coefficients.

Aspect 6. The apparatus of Aspect 5, wherein to reconstruct the decoded data into image blocks, the processing circuitry is further configured to: apply an inverse transform to the decoded transform coefficients to form pixel data; and reconstruct the image blocks from the pixel data.

Aspect 7. The apparatus of any of Aspects 1-6, wherein the parallel vector operations are Single-Instruction-Multiple-Data (SIMD) operations or Single-Instruction-Multiple-Thread (SIMT) operations.

Aspect 8. A method for image decompression, the method comprising: retrieving a plurality of encoded image blocks from memory, each encoded image block comprising encoded vectors; entropy decoding, using parallel vector operations, the encoded vectors using vector-range tree coding (V-RTC) to generate decoded data; and reconstructing the decoded data into image blocks.

Aspect 9. The method of Aspect 8, wherein entropy decoding, using parallel vector operations, the encoded vectors using V-RTC to generate the decoded data comprises: decoding pairs of unsigned integers in the encoded vectors by traversing a range-tree structure to generate unsigned integers, wherein each node of the range-tree structure is associated with a maximum magnitude of a respective node; and converting the unsigned integers to signed integers using a transformation that maps each unique unsigned integer to a unique signed integer.

Aspect 10. The method of Aspect 8, wherein entropy decoding, using parallel vector operations, the encoded vectors using V-RTC to generate the decoded data comprises: decoding pairs of signed integers in the encoded vectors by traversing leaf nodes of a range-tree structure to generate signed integers, wherein each leaf node of the range-tree structure is associated with a maximum magnitude of a respective leaf node; decoding pairs of unsigned integers in the encoded vectors at parent nodes of the range-tree structure to generate unsigned integers, wherein each parent node of the range-tree structure is associated with the maximum magnitude of a respective parent node; and converting the unsigned integers to signed integers using a transformation that maps each unique unsigned integer to a unique signed integer.

Aspect 11. The method of any of Aspects 8-10, further comprising: reconstructing images from the image blocks; and using the images as training data for a neural network.

Aspect 12. The method of any of Aspects 8-1, wherein the encoded vectors are encoded transform coefficients, and wherein the decoded data are decoded transform coefficients.

Aspect 13. The method of Aspect 12, wherein reconstructing the decoded data into image blocks comprises: applying an inverse transform to the decoded transform coefficients to form pixel data; and reconstructing the image blocks from the pixel data.

Aspect 14. The method of any of Aspects 8-13, wherein the parallel vector operations are Single-Instruction-Multiple-Data (SIMD) operations or Single-Instruction-Multiple-Thread (SIMT) operations.

Aspect 15. An apparatus for image compression, the apparatus comprising: at least one memory; and processing circuitry in communication with the at least one memory, the processing circuitry configured to: generate a plurality of image blocks from images stored in the memory, each image block comprising vectors; entropy encode, using parallel vector operations, the vectors using vector-range tree coding (V-RTC) to generate encoded data; and store the encoded data in the memory.

Aspect 16. The apparatus of Aspect 15, wherein to entropy encode, using parallel vector operations, the vectors using V-RTC to generate the encoded data, the processing circuitry is configured to: convert signed integers in the vectors to unsigned integers using a transformation that maps each signed integer to a unique unsigned integer; and encode pair of unsigned integers in the vectors by traversing a range-tree structure to generate the encoded data, wherein each node of the range-tree structure is associated with a maximum magnitude of a respective node.

Aspect 17. The apparatus of Aspect 15, wherein to entropy encode, using parallel vector operations, the vectors using V-RTC to generate the encoded data, the processing circuitry is configured to: convert signed integers to unsigned integers at parent nodes of a range-tree structure; encode pairs of unsigned integers in the vectors at the parent nodes of the range-tree structure to generate the encoded data, wherein each parent node of the range-tree structure is associated with the maximum magnitude of a respective parent node; and encode pairs of signed integers in the vectors by traversing leaf nodes of the range-tree structure to generate the encoded data, wherein each leaf node of the range-tree structure is associated with a maximum magnitude of a respective leaf node.

Aspect 18. The apparatus of any of Aspects 15-17, wherein the vectors are transform coefficients.

Aspect 19. The apparatus of Aspect 18, wherein the processing circuitry is further configured to: apply a transform to pixel data of the image blocks to generate the transform coefficients.

Aspect 20. The apparatus of any of Aspects 15-10, wherein the parallel vector operations are Single-Instruction-Multiple-Data (SIMD) operations or Single-Instruction-Multiple-Thread (SIMT) operations.

Aspect 21. A method for image compression, the method comprising: generating a plurality of image blocks from images stored in memory, each image block comprising vectors; entropy encoding, using parallel vector operations, the vectors using vector-range tree coding (V-RTC) to generate encoded data; and storing the encoded data in the memory.

Aspect 22. The method of Aspect 21, wherein entropy encoding, using parallel vector operations, the vectors using V-RTC to generate the encoded data comprises: converting signed integers in the vectors to unsigned integers using a transformation that maps each signed integer to a unique unsigned integer; and encoding pair of unsigned integers in the vectors by traversing a range-tree structure to generate the encoded data, wherein each node of the range-tree structure is associated with a maximum magnitude of a respective node.

Aspect 23. The method of Aspect 21, wherein entropy encoding, using parallel vector operations, the vectors using V-RTC to generate the encoded data comprises: converting signed integers to unsigned integers at parent nodes of a range-tree structure; encoding pairs of unsigned integers in the vectors at the parent nodes of the range-tree structure to generate the encoded data, wherein each parent node of the range-tree structure is associated with the maximum magnitude of a respective parent node; and encoding pairs of signed integers in the vectors by traversing leaf nodes of the range-tree structure to generate the encoded data, wherein each leaf node of the range-tree structure is associated with a maximum magnitude of a respective leaf node.

Aspect 24. The method of any of Aspect 21-23, wherein the vectors are transform coefficients.

Aspect 25. The method of Aspect 24, further comprising: applying a transform to pixel data of the image blocks to generate the transform coefficients.

Aspect 26. The method of any of Aspects 21-25, wherein the parallel vector operations are Single-Instruction-Multiple-Data (SIMD) operations or Single-Instruction-Multiple-Thread (SIMT) operations.

In one or more examples, the functions described may be implemented in hardware, software, firmware, or any combination thereof. If implemented in software, the functions may be stored on, as one or more instructions or code, a computer-readable medium and executed by a hardware-based processing unit. Computer-readable media may include computer-readable storage media, which corresponds to a tangible medium such as data storage media. In this manner, computer-readable media generally may correspond to tangible computer-readable storage media which is non-transitory. Data storage media may be any available media that can be accessed by one or more computers or one or more processors to retrieve instructions, code and/or data structures for implementation of the techniques described in this disclosure. A computer program product may include a computer-readable medium.

By way of example, and not limitation, such computer-readable storage media can comprise RAM, ROM, EEPROM, CD-ROM or other optical disk storage, magnetic disk storage, or other magnetic storage devices, flash memory, or any other medium that can be used to store desired program code in the form of instructions or data structures and that can be accessed by a computer. It should be understood that computer-readable storage media and data storage media do not include carrier waves, signals, or other transient media, but are instead directed to non-transient, tangible storage media. Disk and disc, as used herein, includes compact disc (CD), laser disc, optical disc, digital versatile disc (DVD), floppy disk and Blu-ray disc, where disks usually reproduce data magnetically, while discs reproduce data optically with lasers. Combinations of the above should also be included within the scope of computer-readable media.

Instructions may be executed by one or more processors, such as one or more digital signal processors (DSPs), general purpose microprocessors, application specific integrated circuits (ASICs), field programmable logic arrays (FPGAs), or other equivalent integrated or discrete logic circuitry. Accordingly, the term “processor,” as used herein may refer to any of the foregoing structure or any other structure suitable for implementation of the techniques described herein. In addition, in some aspects, the functionality described herein may be provided within dedicated hardware and/or software modules configured for encoding and decoding, or incorporated in a combined coder. Also, the techniques could be fully implemented in one or more circuits or logic elements.

The techniques of this disclosure may be implemented in a wide variety of devices or apparatuses, including a wireless handset, an integrated circuit (IC) or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a coder hardware unit or provided by a collection of interoperative hardware units, including one or more processors as described above, in conjunction with suitable software and/or firmware.

This disclosure also includes attached appendices, which forms part of this disclosure and is expressly incorporated herein. The techniques disclosed in the appendices may be performed in combination with or separately from the techniques disclosed herein.

Various examples have been described. These and other examples are within the scope of the following claims.

What is claimed is:

1. An apparatus for image decompression, the apparatus comprising:
at least one memory; and
processing circuitry in communication with the at least one memory, the processing circuitry configured to:
retrieve a plurality of encoded image blocks from the memory, each encoded image block comprising encoded vectors;
entropy decode, using parallel vector operations, the encoded vectors using vector-range tree coding (V-RTC) to generate decoded data; and
reconstruct the decoded data into image blocks.

2. The apparatus of claim 1, wherein to entropy decode, using parallel vector operations, the encoded vectors using V-RTC to generate the decoded data, the processing circuitry is configured to:
decode pairs of unsigned integers in the encoded vectors by traversing a range-tree structure to generate unsigned integers, wherein each node of the range-tree structure is associated with a maximum magnitude of a respective node; and
convert the unsigned integers to signed integers using a transformation that maps each unique unsigned integer to a unique signed integer.

3. The apparatus of claim 1, wherein to entropy decode, using parallel vector operations, the encoded vectors using V-RTC to generate the decoded data, the processing circuitry is configured to:
decode pairs of signed integers in the encoded vectors by traversing leaf nodes of a range-tree structure to generate signed integers, wherein each leaf node of the range-tree structure is associated with a maximum magnitude of a respective leaf node;
decode pairs of unsigned integers in the encoded vectors at parent nodes of the range-tree structure to generate unsigned integers, wherein each parent node of the range-tree structure is associated with the maximum magnitude of a respective parent node; and
convert the unsigned integers to signed integers using a transformation that maps each unique unsigned integer to a unique signed integer.

4. The apparatus of claim 1, wherein the processing circuitry is further configured to:
reconstruct images from the image blocks; and
use the images as training data for a neural network.

5. The apparatus of claim 1, wherein the encoded vectors are encoded transform coefficients, and wherein the decoded data are decoded transform coefficients.

6. The apparatus of claim 5, wherein to reconstruct the decoded data into image blocks, the processing circuitry is further configured to:
apply an inverse transform to the decoded transform coefficients to form pixel data; and
reconstruct the image blocks from the pixel data.

7. The apparatus of claim 1, wherein the parallel vector operations are Single-Instruction-Multiple-Data (SIMD) operations or Single-Instruction-Multiple-Thread (SIMT) operations.

8. A method for image decompression, the method comprising:
retrieving a plurality of encoded image blocks from memory, each encoded image block comprising encoded vectors;
entropy decoding, using parallel vector operations, the encoded vectors using vector-range tree coding (V-RTC) to generate decoded data; and
reconstructing the decoded data into image blocks.

9. The method of claim 8, wherein entropy decoding, using parallel vector operations, the encoded vectors using V-RTC to generate the decoded data comprises:
decoding pairs of unsigned integers in the encoded vectors by traversing a range-tree structure to generate unsigned integers, wherein each node of the range-tree structure is associated with a maximum magnitude of a respective node; and
converting the unsigned integers to signed integers using a transformation that maps each unique unsigned integer to a unique signed integer.

10. The method of claim 8, wherein entropy decoding, using parallel vector operations, the encoded vectors using V-RTC to generate the decoded data comprises:
decoding pairs of signed integers in the encoded vectors by traversing leaf nodes of a range-tree structure to generate signed integers, wherein each leaf node of the range-tree structure is associated with a maximum magnitude of a respective leaf node;
decoding pairs of unsigned integers in the encoded vectors at parent nodes of the range-tree structure to generate unsigned integers, wherein each parent node of the range-tree structure is associated with the maximum magnitude of a respective parent node; and
converting the unsigned integers to signed integers using a transformation that maps each unique unsigned integer to a unique signed integer.

11. The method of claim 8, further comprising:
reconstructing images from the image blocks; and
using the images as training data for a neural network.

12. The method of claim 8, wherein the encoded vectors are encoded transform coefficients, and wherein the decoded data are decoded transform coefficients.

13. The method of claim 12, wherein reconstructing the decoded data into image blocks comprises:
applying an inverse transform to the decoded transform coefficients to form pixel data; and
reconstructing the image blocks from the pixel data.

14. The method of claim 8, wherein the parallel vector operations are Single-Instruction-Multiple-Data (SIMD) operations or Single-Instruction-Multiple-Thread (SIMT) operations.

15. An apparatus for image compression, the apparatus comprising:
at least one memory; and
processing circuitry in communication with the at least one memory, the processing circuitry configured to:
generate a plurality of image blocks from images stored in the memory, each image block comprising vectors;
entropy encode, using parallel vector operations, the vectors using vector-range tree coding (V-RTC) to generate encoded data; and
store the encoded data in the memory.

16. The apparatus of claim 15, wherein to entropy encode, using parallel vector operations, the vectors using V-RTC to generate the encoded data, the processing circuitry is configured to:
convert signed integers in the vectors to unsigned integers using a transformation that maps each signed integer to a unique unsigned integer; and
encode pair of unsigned integers in the vectors by traversing a range-tree structure to generate the encoded data, wherein each node of the range-tree structure is associated with a maximum magnitude of a respective node.

17. The apparatus of claim 15, wherein to entropy encode, using parallel vector operations, the vectors using V-RTC to generate the encoded data, the processing circuitry is configured to:
convert signed integers to unsigned integers at parent nodes of a range-tree structure;
encode pairs of unsigned integers in the vectors at the parent nodes of the range-tree structure to generate the encoded data, wherein each parent node of the range-tree structure is associated with the maximum magnitude of a respective parent node; and
encode pairs of signed integers in the vectors by traversing leaf nodes of the range-tree structure to generate the encoded data, wherein each leaf node of the range-tree structure is associated with a maximum magnitude of a respective leaf node.

18. The apparatus of claim 15, wherein the vectors are transform coefficients.

19. The apparatus of claim 18, wherein the processing circuitry is further configured to:
apply a transform to pixel data of the image blocks to generate the transform coefficients.

20. The apparatus of claim 15, wherein the parallel vector operations are Single-Instruction-Multiple-Data (SIMD) operations or Single-Instruction-Multiple-Thread (SIMT) operations.

21. A method for image compression, the method comprising:
generating a plurality of image blocks from images stored in memory, each image block comprising vectors;
entropy encoding, using parallel vector operations, the vectors using vector-range tree coding (V-RTC) to generate encoded data; and
storing the encoded data in the memory.

22. The method of claim 21, wherein entropy encoding, using parallel vector operations, the vectors using V-RTC to generate the encoded data comprises:
converting signed integers in the vectors to unsigned integers using a transformation that maps each signed integer to a unique unsigned integer; and
encoding pair of unsigned integers in the vectors by traversing a range-tree structure to generate the encoded data, wherein each node of the range-tree structure is associated with a maximum magnitude of a respective node.

23. The method of claim 21, wherein entropy encoding, using parallel vector operations, the vectors using V-RTC to generate the encoded data comprises:
converting signed integers to unsigned integers at parent nodes of a range-tree structure;
encoding pairs of unsigned integers in the vectors at the parent nodes of the range-tree structure to generate the encoded data, wherein each parent node of the range-tree structure is associated with the maximum magnitude of a respective parent node; and
encoding pairs of signed integers in the vectors by traversing leaf nodes of the range-tree structure to generate the encoded data, wherein each leaf node of the range-tree structure is associated with a maximum magnitude of a respective leaf node.

24. The method of claim 21, wherein the vectors are transform coefficients.

25. The method of claim 24, further comprising:
applying a transform to pixel data of the image blocks to generate the transform coefficients.

26. The method of claim 21, wherein the parallel vector operations are Single-Instruction-Multiple-Data (SIMD) operations or Single-Instruction-Multiple-Thread (SIMT) operations.
